(19) United States
(12) Patent Application Publication
(10) Pub. No.: US 2025/0309860 A1
(43) Pub. Date: Oct. 2, 2025

(54) BULK ACOUSTIC RESONATOR WITH PITCH CONSERVING IDT

(71) Applicant: Murata Manufacturing Co., Ltd., Nagaokakyo-shi (JP)

(72) Inventors: Greg DYER, Santa Barbara, CA (US); Bryant GARCIA, Mississauga (CA); Tiberiu JAMNEALA, San Mateo, CA (US)

(21) Appl. No.: 19/086,921

(22) Filed: Mar. 21, 2025

Related U.S. Application Data
(60) Provisional application No. 63/571,643, filed on Mar. 29, 2024.

(51) Int. Cl. H03H 9/13; H03H 9/02; H03H 9/17; H03H 9/56

(52) U.S. Cl. CPC H03H 9/132; H03H 9/02228; H03H 9/131; H03H 9/173; H03H 9/174; H03H 9/176; H03H 9/568

(57) ABSTRACT

A bulk acoustic resonator is provided that includes a piezoelectric layer; first and second busbars on a surface of the piezoelectric layer and that extend along a first direction; and units of fingers that are adjacent to each other. Each of the units of fingers includes a first finger that extends from the first busbar and a second finger that extends from the second busbar. Moreover, a first pitch of each unit of fingers indicates a distance along the first direction between the first finger and the second finger in the respective unit, with the first pitch varying along a second direction that is orthogonal to the first direction. A unit pitch indicates a center-to-center distance along the first direction between respective first fingers of adjacent units that extend from the first busbar, with the unit pitch being substantially constant across the plurality of units of fingers.

### CROSS REFERENCE TO RELATED APPLICATIONS

This application claims priority to U.S. Provisional Application No. 63/571,643, filed Mar. 29, 2024, the entire contents of which are hereby incorporated by referenced.

### TECHNICAL FIELD

This disclosure relates to radio frequency filters using acoustic wave resonators, and more specifically, to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate with mitigated spurs and enhanced power handling performance.

### SUMMARY

Skewing IDTs through a pitch conservation may achieve suppress longitudinal spurs without spatial inhomogeneity over the acoustic track and may result in a smooth and ripple-free (or with reduced ripples) response. A bulk acoustic resonator, a filter device including the bulk acoustic resonator, and a radio frequency module including the filter device are provided.

Specifically, in an exemplary aspect, a bulk acoustic resonator is provided that includes a piezoelectric layer; a first busbar and a second busbar that are disposed on a surface of the piezoelectric layer and that extend along a first direction of the surface of the piezoelectric layer; and a plurality of units of fingers at a surface of the piezoelectric layer and that are adjacent to each other. In the exemplary aspect, each unit of the plurality of units of fingers includes a first finger that extends from the first busbar and a second finger that extends from the second busbar and that is adjacent to the respective first finger. Moreover, a first pitch of each unit of the plurality of units of fingers indicates a distance along the first direction between the first finger and the second finger in the respective unit, with the first pitch varying along a second direction that is orthogonal to the first direction. In addition, a unit pitch indicates a center-to-center distance along the first direction between respective first fingers of adjacent units of the plurality of units of fingers that extend from the first busbar, with the unit pitch being substantially constant across the plurality of units of fingers.

In an exemplary aspect, the unit pitch is substantially constant along the second direction.

In another exemplary aspect, the unit pitch between a first two adjacent units is identical to the unit pitch between a second two adjacent units.

In another exemplary aspect, the unit pitch between the first and second two adjacent units at a location y of the second direction is equal to a sum of the first pitch between the first finger and the second finger in one of the two adjacent units at the location y and a second pitch between the second finger in the one of the two adjacent units and the first finger in another unit of the two adjacent units at the location y. In this aspect, the first pitch is not equal to the second pitch.

In another exemplary aspect, the first finger in the unit of the plurality of units includes a first plurality of linear segments, and an adjacent pair of linear segments in the first plurality of linear segments has different slopes from each other and intercepts at a vertex. Moreover, a shape and a size of the second finger in the unit of the plurality of units are identical to a shape and a size of the first finger in the unit of the plurality of units, respectively; and respective vertices of the first and second fingers in the unit of the plurality of units are offset relative to each other in the second direction.

In another exemplary aspect, a number of the first plurality of linear segments in the first finger is at least 2, and at least a portion of the first finger and the second finger are V-shaped.

In another exemplary aspect, a number of the first plurality of linear segments in the first finger is 2 and the first finger has a V-shape, the second finger in the unit of the plurality of units has a V-shape that is mirror symmetric with respect to the V-shape of the first finger, and the first pitch between the first finger and the second finger at a mid-location between the first busbar and the second busbar along the second direction is larger than the first pitch between the first finger and the second finger at an edge location along the second direction.

In another exemplary aspect, the first finger in the unit of the plurality of units has a curved shape, the second finger in the unit of the plurality of units has a curved shape that is mirror symmetric with respect to the curved shape of the first finger, and the first pitch between the first finger and the second finger at a mid-location between the first busbar and the second busbar along the second direction is larger than the first pitch between the first finger and the second finger at an edge location along the second direction.

In another exemplary aspect, the first finger in the unit of the plurality of units has a sinusoidal shape, and the second finger in the unit of the plurality of units has a sinusoidal shape that is mirror symmetric with respect to the sinusoidal shape of the first finger.

In an exemplary aspect, a filter device is provided that includes a plurality of bulk acoustic resonators connected in parallel. In this aspect, at least one of the plurality of bulk acoustic resonators includes a piezoelectric layer; a first busbar and a second busbar that are disposed on a surface of the piezoelectric layer and that extend along a first direction of the surface of the piezoelectric layer; and a plurality of units of fingers at a surface of the piezoelectric layer and that are adjacent to each other. In this aspect, each unit of the plurality of units of fingers includes a first finger that extends from the first busbar and a second finger that extends from the second busbar and that is adjacent to the respective first finger. Moreover, a first pitch of each unit of the plurality of units of fingers indicates a distance along the first direction between the first finger and the second finger in the respective unit, with the first pitch varying along a second direction that is orthogonal to the first direction. Furthermore, a unit pitch indicates a center-to-center distance along the first direction between respective first fingers of adjacent units of the plurality of units of fingers that extend from the first busbar, with the unit pitch being substantially constant across the plurality of units of fingers.

In another exemplary aspect, a radio frequency module is provided that includes a filter device including plurality of bulk acoustic resonators connected in parallel; and a radio frequency circuit coupled to the filter device, the filter device and the radio frequency circuit being enclosed within a common package. In this aspect, at least one of the plurality of bulk acoustic resonators of the filter device includes a piezoelectric layer; a first busbar and a second busbar that are disposed on a surface of the piezoelectric layer and that extend along a first direction of the surface of the piezoelectric layer; and a plurality of units of fingers at a surface of the piezoelectric layer and that are adjacent to each other. Moreover, each unit of the plurality of units of fingers includes a first finger that extends from the first busbar and a second finger that extends from the second busbar and that is adjacent to the respective first finger. In addition, a first pitch of each unit of the plurality of units of fingers indicates a distance along the first direction between the first finger and the second finger in the respective unit, with the first pitch varying along a second direction that is orthogonal to the first direction. Furthermore, a unit pitch indicates a center-to-center distance along the first direction between respective first fingers of adjacent units of the plurality of units of fingers that extend from the first busbar, with the unit pitch being substantially constant across the plurality of units of fingers.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and a cross-sectional view of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIGS. 6-7 shows a top view of a portion of an example of a bulk acoustic resonator including an IDT according to an exemplary aspect.

FIG. 8 shows an example of a relationship between a pitch and a y location according to an aspect of the disclosure.

FIGS. 9-13 shows top views of respective portions of bulk acoustic resonators according to an exemplary aspect.

FIGS. 14-18 compare the performance of three bulk acoustic resonators with the three respective IDT configurations according to an aspect of the disclosure.

FIGS. 19A and 19B show an example of an IDT configuration according to an aspect of the disclosure.

FIG. 20 shows an example of an IDT finger configuration according to an aspect of the disclosure.

FIGS. 21, 22, 23A and 23B compare magnitudes of the admittance (FIG. 21), real components of the admittance (FIG. 22), and spatial heat distributions by frequency (FIGS. 23A and 23B) of three different IDT configurations according to some examples of the disclosure.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed bulk acoustic resonator, a filter device, a radio frequency module, and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

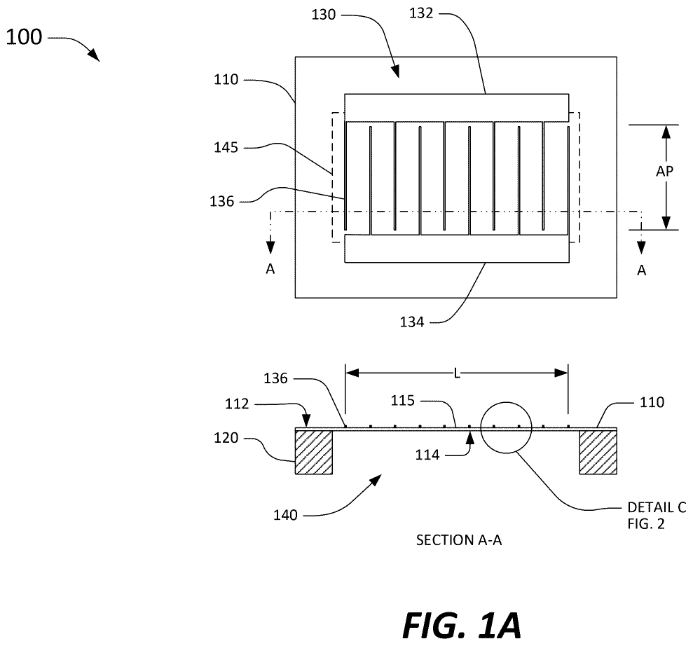

FIG. 1A shows a simplified schematic top view and orthogonal cross-sectional views of a bulk acoustic resonator device, namely a transversely excited film bulk acoustic resonator (XBAR) 100. XBAR resonators, such as the resonator 100, may be used in a variety of RF filters including band-rejection filters, band-pass filters, duplexers, and multiplexers. XBARs are particularly suited for use in filters for communications bands with frequencies above 3 GHz.

In general, the XBAR 100 includes a conductor pattern (e.g., a thin film metal layer) formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and exactly parallel to each other. For example, due to the manufacturing variances result from the deposition process, the front side 112 and back side 114 may have undulations of the surface as would be appreciated to one skilled in the art. Moreover, the term “substantially” as used herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/or” unless explicitly indicated to refer to alternatives only or if the alternatives are mutually exclusive.

According to an exemplary aspect, the piezoelectric layer is a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Z-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120-90, 0) and (0, 128-90, 0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer, such as a silicon oxide layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other that can be “substantially” parallel to each other due to minor variations, such as due to manufacturing tolerances, for example. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

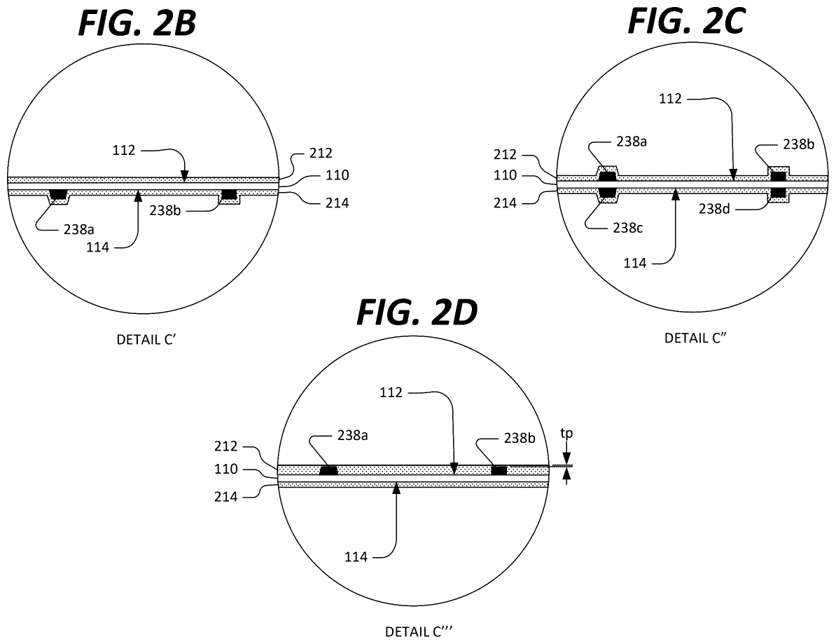

The first and second busbars 132, 134 are configured as the terminals of the XBAR 100 with the plurality of interleaved fingers extending therefrom. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4.

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example silicon oxide or silicon dioxide, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other to provide a stack of materials.

Moreover, in the example of FIG. 1B, the cavity 140 is defined on all sides by the dielectric layer 124. However, in other exemplary embodiments, one or more sides of the cavity 140 may be defined by the substrate 120 or the piezoelectric layer 110. In the example of FIG. 1B, the cavity 140 has a trapezoidal shape. However, as noted above, cavity shape is not limited and may be rectangular, oval, or other shapes.

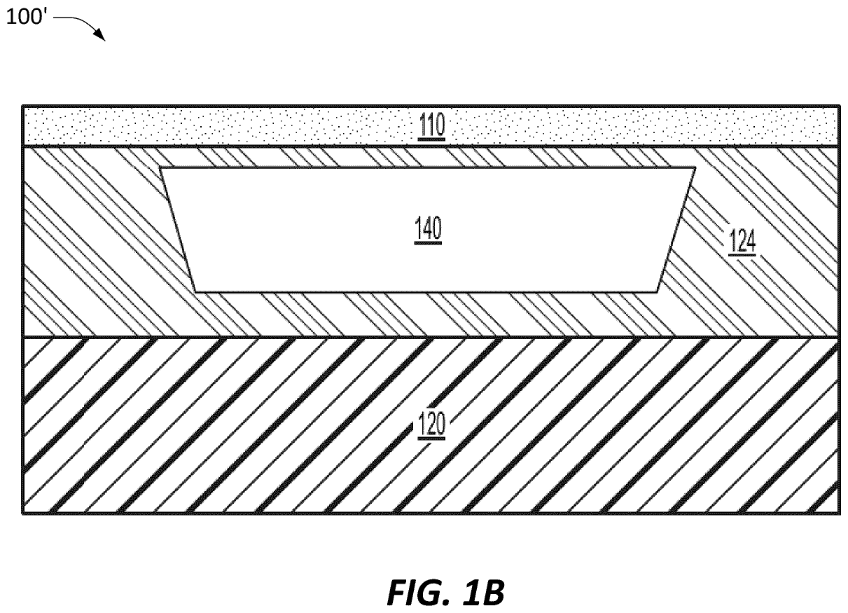

FIG. 2A shows a detailed schematic cross-sectional view of the XBAR 100 of FIG. 1A or 1B. The piezoelectric layer 110 is a single-crystal layer of piezoelectrical material having a thickness ts. ts may be, for example, 100 nm to 1500 nm. When used in filters for 5G NR and Wi-Fi™ bands from 3.4 GHZ to 7 GHZ, the thickness ts may be, for example, 150 nm to 500 nm. The thickness ts can be measured in a direction substantially perpendicular or orthogonal to a surface of the piezoelectric layer in an exemplary aspect.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon oxide, silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. In exemplary aspects, either or both of the front side and back side dielectric layers 212, 214 may be formed of multiple layers of two or more materials according to various exemplary aspects.

The IDT fingers 238a, 238b may be aluminum, substantially (i.e., predominantly) aluminum alloys, copper, substantially (i.e., predominantly) copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects. In general, it is noted that the terms “comprise”, “have”, “include” and “contain” (and their variants) as used herein are open-ended linking verbs and allow the addition of other elements when used in a claim. Moreover, the use of the word “a” or “an” when used in conjunction with the term “comprising” in the claims or the specification means one or more than one, unless the context dictates otherwise.

Dimension p is the center-to-center spacing between adjacent IDT fingers, such as the IDT fingers 238a, 238b in FIGS. 2A-2C. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, according to an exemplary aspect as will be discussed in more detail below, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A, 2B, and 2C, has a width w measured normal to the long direction of each finger. The width w may also be referred to herein as the “mark.” In general, the width of the IDT fingers may be constant over the length of the IDT, in which case the dimension w may be the width of each IDT finger. However, in an exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction parallel to the length L of the IDT, as defined in FIG. 1A.

In general, the IDT of an XBAR differs substantially from the IDTs used in surface acoustic wave (SAW) resonators, primarily in that IDTs of an XBAR excite a primary shear acoustic mode (also referred to as a primary shear mode, a primary shear thickness mode, or the like), as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers (i.e., on the opposing surfaces of the piezoelectric layer) can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to deal and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration (identified as Detail C′) in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM-XBAR). It is noted that FIG. 2E generally discloses a similar cross section as that of FIG. 1A, except having a solidly mounted configuration. In this aspect, the SM-XBAR includes a piezoelectric layer 110 and an IDT (of which only two IDT fingers 238 are visible) with a dielectric layer 212 disposed on the piezoelectric layer 110 and IDT fingers 238. The piezoelectric layer 110 has parallel front and back surfaces similar to the configurations described above. Dimension ts is the thickness of the piezoelectric layer 110. The width of the IDT fingers 238 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials (e.g., one or more dielectric layers) may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 238a and 238b, may be disposed on a surface of the front side 112 of the piezoelectric layer 110. Alternatively, IDT fingers, such as IDT finger 238a and 238b, may be disposed in grooves formed in the surface of the front side 112. The grooves may extend partially through the piezoelectric layer. Alternatively, the grooves may extend completely through the piezoelectric layer.

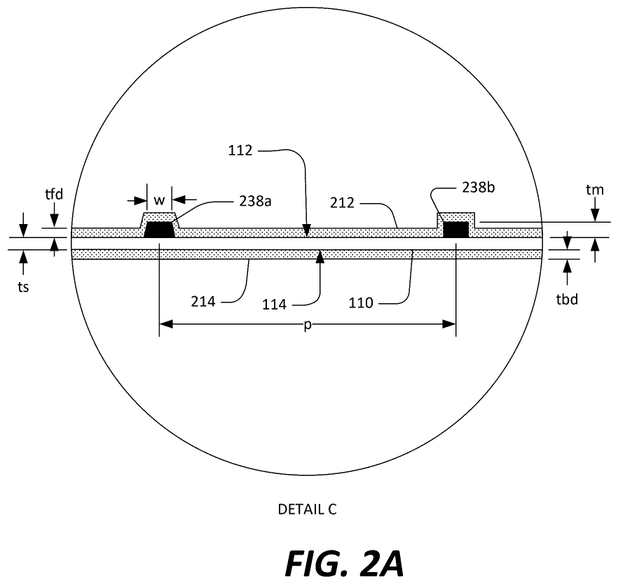

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

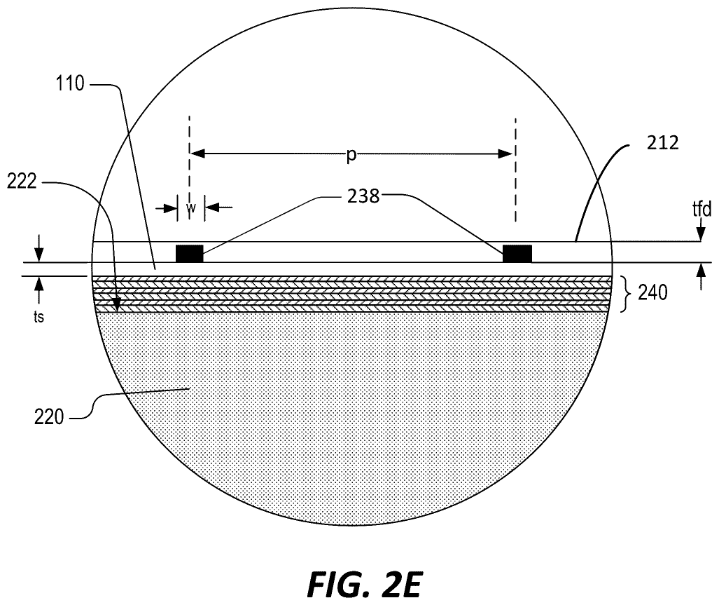

FIG. 5A is a schematic circuit diagram and layout for a high frequency bandpass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, that has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least two shunt resonators, such as the shunt resonators 520A and 520B, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of three series and two shunt resonators is an example. A filter may have more or fewer than five total resonators, more or fewer than three series resonators, and more or fewer than two shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 can be formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, 510C and 510D and the shunt resonators 520A, 520B and 520C can have an XBAR configuration as described above with respect to FIGS. 1A-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 2E), which in turn can be mounted on a substrate.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or RF circuit) 543. In an exemplary aspect, the acoustic wave filters 544 may include one or more of filter 500 including XBARs (e.g., the bulk acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

In some aspects, spurious longitudinal Lamb modes in piezoelectric plate may present challenges for the design of XBAR filters. In some examples, A0-N and S0-N modes are present in resonators over a bandwidth of a filter. In this regard, “chirping” may be used to disrupt or otherwise address spurious longitudinal modes. Chirping generally refers to chirping of widths (e.g., marks) or pitches of IDT fingers. In an example, chirping refers to an increase of widths followed by a decrease of widths with a number of the IDT fingers or vice versa. In an example, chirping refers to an increase of pitches followed by a decrease of pitches with a number of the IDT fingers or vice versa. However, in some examples, chirping may lead to spatially inhomogeneous spur resonances in an acoustic track and discrete (and weaker) ripples in the filter insertion loss (IL). Aspects of the disclosure are related to an IDT design technique and configuration to reduce quality factors (Q-factors) of respective spurious longitudinal modes, e.g., de-Q or suppress the spurious longitudinal modes, with minimal impact on the XBAR mode (e.g., the main XBAR mode). In an aspect, skewing IDTs through a pitch conservation may achieve a similar spectral dispersion of longitudinal spurs as that of chirping, however without spatial inhomogeneity over the acoustic track and with a smooth and ripple-free (or with reduced ripples as compared with ripples in chirping) response.

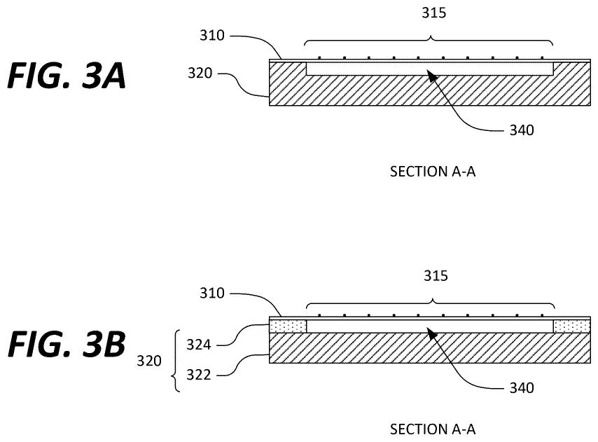

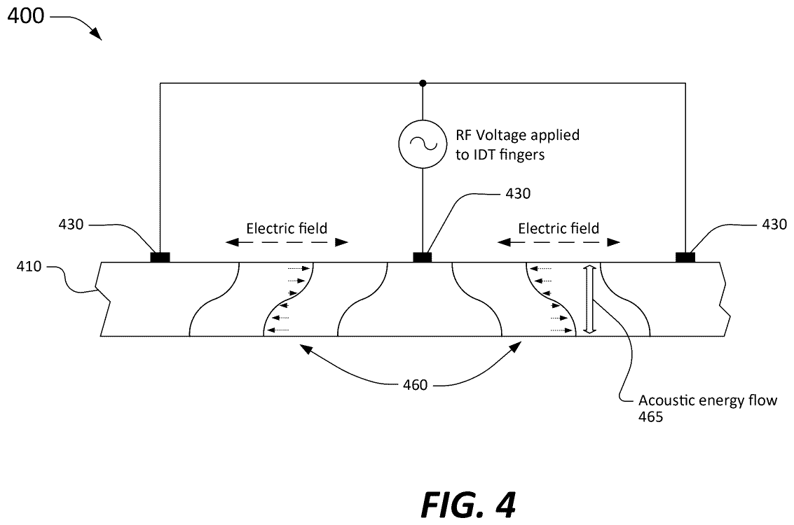

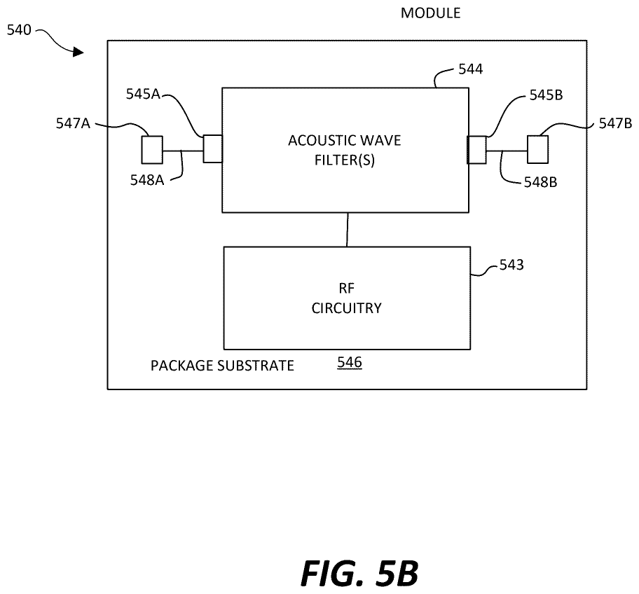

According to an aspect of the disclosure, a bulk acoustic resonator can include a piezoelectric layer, a first busbar and a second busbar that are disposed on a surface of the piezoelectric layer and extend along a first direction, and an IDT over the surface of the piezoelectric layer. The IDT can include a plurality of units of fingers that are adjacent to each other. In an aspect, each unit of the plurality of units of fingers may include a first finger that extends from the first busbar and a second finger that extends from the second busbar. A first pitch may indicate a distance along the first direction (e.g., the X direction and/or the lengthwise direction in FIGS. 6-7 and 9-13) between the first finger and the second finger in the respective unit. The first pitch may vary along a second direction (e.g., the Y direction and/or the widthwise direction in FIGS. 6-7 and 9-13) that is orthogonal to the first direction. Further, a unit pitch may indicate a distance along the first direction between two adjacent units of the plurality of units of fingers. In other words, the unit pitch indicates a center-to-center distance along the first direction (i.e., the X direction) between respective first fingers of adjacent units of the plurality of units of fingers. According to the exemplary aspect, the unit pitch may remain unchanged, i.e., the unit pitch is constant or substantially constant across the plurality of units of fingers and, in particular, along the second direction. Various IDT geometries may satisfy the above conditions. The IDT geometries may include any suitable shape(s) of the first finger and/or the second finger in the respective unit. In an exemplary aspect, the first finger has a linear shape such as shown in FIGS. 6-7. In another exemplary aspect, the first finger has a nonlinear shape (e.g., an oval shape, a V-shape, or the like) such as shown in FIGS. 9-13.

It is noted that in exemplary aspects, the bulk acoustic resonators according to the exemplary aspect can have IDT configurations in which one or more sections of IDT interleaved fingers are chirped from section to section. In general, chirping is considered a variance of the pitch, the mark, or both, in the IDT of an XBAR and can be used to suppress undesirable spurious magnitudes for small signal or large signal performance gains that otherwise depend upon pitch and/or mark, such as metal and propagating modes, with only slight broadening of the primary mode resonance. According to exemplary aspects, an IDT can a plurality of sections that each include at least one (or a plurality of) units of fingers). Each section can have a constant pitch or mark within each section but can be chirped from section to section by varying the pitch or mark from one section to another section in order to address possible spurious modes.

FIGS. 6-7 shows a top view of a portion of a bulk acoustic resonator 600 including an IDT 630 according to an aspect of the disclosure, although the individual components of the bulk acoustic resonator 600 are not shown in detail. The resonator of FIGS. 6-7 may have, for example, the XBAR configuration 100 or 100′ including any of the configurations of FIGS. 1A-3B or any combination thereof. The bulk acoustic resonator 600 may include a piezoelectric layer (not shown in FIGS. 6-7) and a first busbar 632 and a second busbar 634 that are disposed on a surface (not shown in FIGS. 6-7) of the piezoelectric layer and extend along the first direction (i.e., the X direction) of a surface of the piezoelectric layer. It should be appreciated that the busbars can generally correspond to busbars 132 and 134 of FIG. 1A in an exemplary aspect as described above.

It should be appreciated that the first busbar 632 and the second busbar 634 can have any suitable shape(s). In the example shown in FIGS. 6-7, the first busbar 632 and the second busbar 634 have a rectangular shape and extend in a parallel direction to each other. It is noted that the IDT 130 can include a plurality of units of fingers that are adjacent to each other. In an aspect, each unit of the plurality of units of fingers may include a first finger that extends from the first busbar 632 and a second finger that extends from the second busbar 634. Thus, a unit can comprise two interleaved fingers in an exemplary aspect.

FIG. 6 shows an example of a unit 621 of the plurality of units of fingers and various pitches. FIG. 7 shows the unit 621 of the plurality of units of fingers and an example of a unit 622 of the plurality of units of fingers. The unit 622 is adjacent to the unit 621. Referring to FIGS. 6-7, the unit 621 of the plurality of units of fingers includes a first finger 612 and a second finger 613 that are adjacent to each other. The unit 622 of the plurality of units of fingers includes a first finger 614 and a second finger 615. A finger 611 is extended from the second busbar 634 and may be included in a unit that is to the left of the unit 621.

According to the exemplary aspects, the first fingers 612 and 614 in the respective units 621 and 622 may have a linear shape. In the example shown in FIGS. 6-7, the second fingers 613 and 615 in the respective units 621 and 622 may have a linear shape. Referring to FIG. 6, the first fingers 612 and 614 form an angle −θ relative to a plane 635 that is substantively perpendicular (or normal) to a surface of the first busbar 632. In some cases, plane 635 is substantially perpendicular to an inner edge of the first busbar 632 between fingers, such as fingers 612 and 614. In an example, the second fingers 613 and 615 form an angle θ relative to a plane 636 that is substantively perpendicular to a surface of the second busbar 634. In some cases, plane 636 is substantially perpendicular to an inner edge of the second busbar 634 between fingers, such as an edge of the second busbar 634 fingers 611 and 613. In other examples, the second fingers 613 and 615 may form an angle that is different from the angle θ with the plane 636 of the second busbar 634. The angle θ may be referred to as a tilt angle.

Referring to the unit 621 in FIG. 6, the first finger 612 is tilted or angled by −θ from the plane (or direction) 635 that is substantively perpendicular to the surface of the first busbar 632, and the second finger 613 is tilted or angled by θ from the plane (or direction) 636 that is substantively perpendicular to the surface of the second busbar 634. Accordingly, a first pitch p₁ indicating a distance along the first direction X between the first finger 612 and the second finger 613 in the unit 621 varies along the length of the respective fingers in the second direction Y. That is, the first pitch p₁ varies along the second direction Y and may be indicated by p₁(y). The second direction Y is orthogonal or orthogonal to the first direction X. Referring to FIG. 6, an average pitch for the unit 621 including the IDT finger pair 612 and 613 is p₀. A variance in the first pitch p₁(y) may be determined by the tilt angle θ. In an example, a minimum first pitch pₘᵢₙ is p₀-w_{AP} tan(θ) where w_{AP} is the width of the aperture AP of the IDT 630, and a maximum first pitch pₘₐₓ is p₀+w_{AP} tan(θ). In an example, p₁(y) increases from pₘᵢₙ to pₘₐₓ as the y position moves from a position y₁ at a top of the aperture that is close to the first busbar 632 to a position y₂ at a bottom of the aperture that is close to the second busbar 634. When the y position is at a position y_{mid} that is a middle position between the first busbar 632 and the second busbar 634, the first pitch is p₀.

Thus, as illustrate in FIG. 6, for example, the first pitch of each unit of the plurality of units of fingers can be a distance along the first direction between the first finger and the second finger in each respective unit. As described in detail herein, the first pitch varies along the second direction Y that is orthogonal to the first direction X.

As further described above, the first pitch p₁ may indicate the distance along the first direction X between the first finger 612 and the second finger 613 in the unit 621. Further, a second pitch p₂ may indicate a distance along the first direction X between a second finger in a unit and a first finger in an adjacent unit where the second finger in the unit is adjacent to the first finger in the adjacent unit. Referring to FIG. 7, a second pitch p₂ may indicate a distance along the first direction X between the second finger 613 in the unit 621 and the first finger 614 in the unit 622. For the reasons described above, the second pitch p₂ may vary with the second direction Y and may be indicated by p₂(y). Thus, a pitch between adjacent fingers in the IDT 630 may vary along the second direction Y and vary along the first direction X as p₁(y) may be different from p₂(y). Referring to FIGS. 6-7, p₁(y) may be different from p₂(y) when y is not y_{mid}. When y is y_{mid}, p₁(y) and p₂(y) are p₀ in the exemplary aspect.

The first pitch p1, the second pitch p2, the unit pitch, or any pitch in the disclosure can be defined or measured using any suitable method, such as described in the disclosure. A pitch (e.g., the first pitch p1, the second pitch p2 or the unit pitch) may be measured as an edge-to-edge spacing between adjacent IDT fingers such as a spacing from an outer edge of one finger to an outer edge of an adjacent finger. A pitch (e.g., the first pitch p1, the second pitch p2 or the unit pitch) can also be measured using a center-to-center spacing such as similar or identical to that shown in FIG. 2A. The unit pitch may also be measured or defined as a center-to-center spacing between two adjacent units (e.g., the units 621-622).

In an aspect, the unit 621 or 622 includes a pair of IDT fingers and may be referred to as a pitch conserving IDT pair when the average pitch (e.g., the averaged p₁(y)) for the pair of IDT fingers is a constant such as p₀ such as described in FIG. 6.

In an aspect, referring to FIG. 7, if a pair of IDT fingers are defined between two (parallel) busbars (e.g., the unit 621 between the first busbar 632 and the second busbar 634), the pair of IDT fingers (e.g., the unit 621) may be referred to as pitch conserving IDT fingers when (p₁(y)+p₂(y))/2 is a constant such as p₀. Accordingly, p₁(y)+p₂(y) is a constant such as 2p₀.

In an aspect, a unit pitch pᵤₙᵢₜ indicating a distance along the first direction X between two adjacent units (e.g., 621-622) of the plurality of units of fingers may remain unchanged. The unit pitch pᵤₙᵢₜ may be defined or measured using any other suitable methods, such as a center-to-center spacing such as similar or identical to that shown in FIGS. 2A and 7. Referring to FIG. 7, the unit pitch pᵤₙᵢₜ may be defined a center-to-center distance between the first fingers in two adjacent units, such as a distance between a center of the first finger 612 in the unit 621 and a center of the first finger 614 in the unit 622, such as pᵤₙᵢₜ=p₁(y)+p₂(y) (e.g., 2p₀). The unit pitch pᵤₙᵢₜ may remain unchanged (e.g., a constant) along the first direction X. The unit pitch pᵤₙᵢₜ may be defined or measured as an edge-to-edge spacing between adjacent first fingers in adjacent units such as a spacing from an outer edge of a first finger to an outer edge of another first finger.

In an aspect, the unit 621 may include multiple regions, such as (i) a first segment 641 that is between the first finger 612 and the second finger 613, (ii) a portion (e.g., 50%) of a second segment 642, and (iii) a portion (e.g., 50%) of a second segment 643. The second segment 642 may be a region between the second finger 611 of another unit that is adjacent to the unit 621 on one side (e.g., the left side) and the first finger 612 in the unit 621. The second segment 643 may be a region between the second finger 613 of the unit 621 and the first finger 614 in the unit 622. The unit pitch pᵤₙᵢₜ may be defined or measured as pᵤₙᵢₜ=p₂(y)/2+p₁(y)+p₂(y)/2 which is a distance between a center of the second segment 642 and a center of the second segment 643.

In an aspect, the unit pitch pᵤₙᵢₜ between first two adjacent units (e.g., the unit 621 and the adjacent unit to the left of the unit 621) is identical (or substantially identical) to the unit pitch between second two adjacent units (e.g., the units 621-622).

According to an exemplary aspect, the unit pitch pᵤₙᵢₜ between the two adjacent units (e.g., the units 621-622) at a location y of the second direction Y may be equal to a sum of the first pitch p₁(y) between the first finger and the second finger in one (e.g., the unit 621) of the two adjacent units at the location y and a second pitch p₂(y) between the second finger (e.g., 613) in the one (e.g., the unit 621) of the two adjacent units and the first finger (e.g., 614) in another unit (e.g., the unit 622) of the two adjacent units at the location y. In this aspect, the first pitch p₁(y) between the first finger and the second finger is different than the second pitch p₂(y) between the first finger and the second finger.

As described above, the unit pitch pᵤₙᵢₜ may be conserved along the first direction X (e.g., different units have the identical the unit pitch pᵤₙᵢₜ) and along the second direction Y (e.g., the unit pitch pᵤₙᵢₜ of a single unit such as the unit 621 may be a constant 2p₀ that does not depend on the location Y). The average pitch of the unit 621 may be constant in both the first direction X and the second direction Y. The plurality of units of fingers in the IDT 630 may be referred to as pitch conserving if the unit pitch pᵤₙᵢₜ is conserved along the first direction X and/or along the second direction Y. The plurality of units of fingers in the IDT 630 may be referred to as pitch conserving if the average pitch of the unit 621 may be constant in the first direction X and/or the second direction Y.

In an example, a relationship between a frequency f_{N} of a longitudinal harmonic and a pitch between two adjacent IDT fingers is described

$${f}_{N} = N \frac{{v}_{a c o u s t i c}}{2 p} .$$

is an order of the longitudinal harmonic, p is a nominal pitch, v_{acoustic} is the velocity of the acoustic mode. Thus, a ratio

$$\frac{δ {f}_{N}}{{f}_{N}}$$

of a frequency change δf_{N} over the frequency f_{N} is equal to a skew of the pitch. The skew of the pitch may be a ratio of a pitch change δp over the pitch p, such as

$$\frac{δ {f}_{N}}{{f}_{N}} = - \frac{δ p}{p} .$$

In an example, the skew of the pitch may be calculated using a percentage pitch change. Based on the relationship between the skew of the pitch and the relative frequency change, a 1% variation in the pitch can change (e.g., de-Q) the resonance frequency by 1%, and thus a Q factor of the longitudinal harmonic is not greater than 100. Increasing the skew of the pitch may further reduce the Q factor, and thus suppressing the spurious modes. In an example, effects of a relatively small change (e.g., a few percent) of the pitch on the resonance frequency of the main XBAR mode is relatively small, e.g., smaller than the effect on the spurious modes. Thus, varying the pitch along the first direction X and/or the second direction Y while conserving the unit pitch and/or the average pitch along the first direction X and/or the second direction Y can suppress (e.g., de-Q) spurious modes and have less effects on the main XBAR mode.

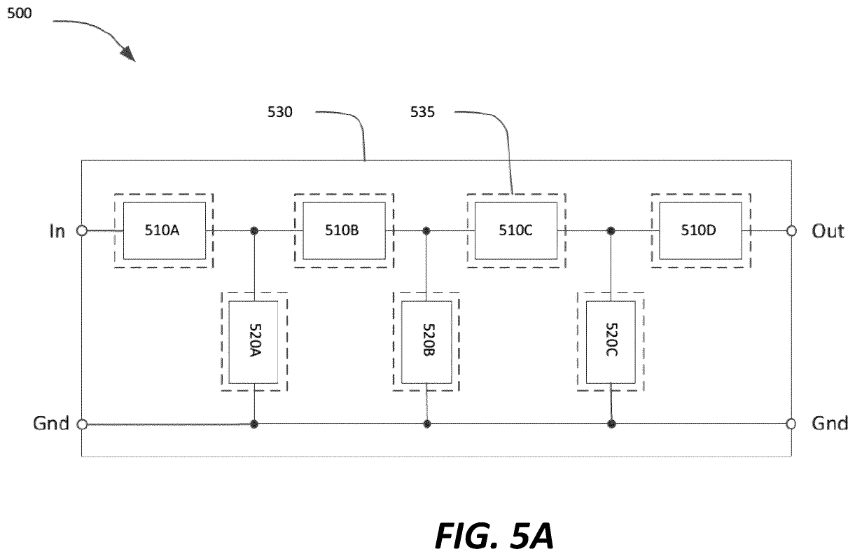

FIG. 8 shows an example of a relationship between a pitch and a y location according to an exemplary aspect of the disclosure. A straight line 801 indicates an average pitch (e.g., p₀ which is normalized as 1), which remains unchanged along the second direction Y (e.g., Normalized aperture), as described above. A straight line 802 indicates a pitch p₁(y) along the second direction Y of a first unit of fingers (e.g., a unit cell of “Segment A”). The pitch p₁(y) increases linearly from the pₘᵢₙ (e.g., 0.99p₀ indicated by a normalized number 0.99) at y1 (e.g., −0.5 of the Normalized aperture) to the pₘₐₓ (e.g., 1.01p₀ indicated by a normalized number 10.01) at y2 (e.g., 0.5 of the Normalized aperture). A straight line 803 indicates a pitch p₁(y) along the second direction Y of a second unit of fingers (e.g., a unit cell of “Segment B”). The pitch p₁(y) decreases linearly from the pₘₐₓ (e.g., 1.01p₀ indicated by a normalized number 10.01) at y1 (e.g., 0.5 of the Normalized aperture) to the pₘᵢₙ (e.g., 0.99p₀ indicated by a normalized number 0.99) at y1 (e.g., −0.5 of the Normalized aperture).

FIGS. 9-13 show examples of units of IDT fingers having geometries different from the linear geometry shown in FIGS. 6-7.

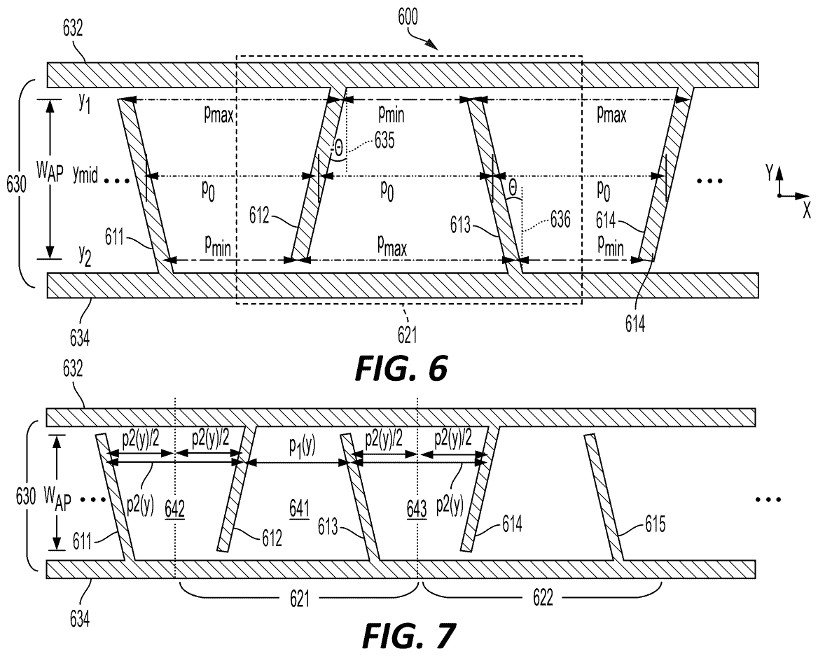

In particular, FIGS. 9-10 show examples of units of IDT fingers where a first finger in the unit of the plurality of units of fingers may include a first plurality of linear segments, and an adjacent pair of linear segments in the first plurality of linear segments have different slopes and intercepts at a vertex. Accordingly, at least of the first finger (and a mirror symmetric second finger) in each unit is nonlinear.

In this aspect, FIG. 9 shows a top view of a portion of a bulk acoustic resonator 900 including an IDT 930 according to an aspect of the disclosure, although the individual components of the bulk acoustic resonator 900 are not shown in detail. The resonator of FIG. 9 may have, for example, the XBAR configuration 100 or 100′ including any of the configurations of FIGS. 1A-3B or any combination thereof. The bulk acoustic resonator 900 may include a piezoelectric layer (not shown) and a first busbar 932 and a second busbar 934 that are disposed on a surface of the piezoelectric layer and extend along the first direction X. It should be appreciated that the busbars can generally correspond to busbars 132 and 134 of FIG. 1A or the busbars 632 and 634 of FIGS. 6-7 in an exemplary aspect as described above.

It should also be appreciated that the first busbar 932 and the second busbar 934 can have any suitable shape(s). In the example shown in FIG. 9, the first busbar 932 and the second busbar 934 have a rectangular shape and can extend in a direction substantially parallel to each other.

The IDT 930 can include a plurality of units of fingers that are adjacent to each other. In an aspect, each unit of the plurality of units of fingers may include a first finger that extends from the first busbar 932 and a second finger that extends from the second busbar 934.

FIG. 9 shows an example of a unit 921 of the plurality of units of fingers and various pitches. Referring to FIG. 9, the unit 921 of the plurality of units of fingers includes a first finger 912 and a second finger 913. A finger 911 extends from the second busbar 934 and may be included in a unit that is to the left of the unit 921. A finger 914 extends from the first busbar 932 and may be included in a unit that is to the right of the unit 921.

In an aspect, the first finger 912 in the unit 921 may include a first plurality of linear segments A-B. An adjacent pair of linear segments A-B in the first finger 912 may have different slopes and may intercept at a vertex V1. A number of the first plurality of linear segments in the first finger 912 is 2, and the first finger 912 is V-shaped. The V-shape of the first finger 912 may also be referred to as a Chevron shape. In general, a number of the first plurality of linear segments in the first finger can be any suitable number, such as 2, 3, 4, or the like according to alternative exemplary aspects.

The second finger 913 in the unit 921 may have any suitable shape, such as a linear shape, a nonlinear shape, or the like. In the example shown in FIG. 9, the second finger 913 includes a second plurality of linear segments A-B that may have different slopes and intercept at a vertex V2. A shape and a size of the second finger 913 in the unit 921 may be identical (or substantially identical) to or different from to a shape and a size of the first finger 912 in the unit 921, respectively. In the example shown in FIG. 9, the first finger 912 and the second finger 913 have the identical shape (e.g., the V-shape) and the identical size. In an example, a first location (e.g., indicated by the location of the vertex V1) of the first finger 912 may be shifted from a second location (e.g., indicated by the location of the vertex V2) of the second finger 913 along the second direction Y. In other words, the respective vertices of the first finger 912 and the second finger 913 in the unit of the plurality of units are offset relative to each other in the second location (i.e., the Y direction).

It should be appreciated that the descriptions with reference to FIGS. 6-7 may be suitably adapted to FIG. 9. A first pitch p₁ indicating a distance along the first direction X between the first finger 912 and the second finger 913 in the unit 921 may vary. The first pitch p₁ may vary with the second direction Y and may be indicated by p₁(y). Referring to FIG. 9, an average pitch for the unit 921 including the IDT finger pair 912 and 913 is p₀. In an example, p₁(y) is p₁₀ when the y location is between a position y₁ that is close to the first busbar 932 and a position yᵥ₂ which is the y location of V2. In an example, p₁(y) is p₂₀ when the y location is between a position y₂ that is close to the second busbar 934 and a position yᵥ₁ which is the y location of V1. In an example, p₁(y) is between p₁₀ and p₂₀ when the y location is between yᵥ₂ and yᵥ₁ which is the y location of V1. As can be seen in FIG. 9, the first pitch between the first finger 912 and the second finger 913 at a mid-location (e.g., bisect yᵥ₁ and yᵥ₂) between the first busbar 932 and the second busbar 934 along the second direction (i.e., the Y direction) is larger than the first pitch between the first finger 912 and the second finger 913 at an edge location along the second direction. In this example, the edge location is closer or at the tips of either the first finger 912 and/or the second finger 913 in the second direction.

A second pitch p₂ may indicate a distance along the first direction X between a second finger in a unit and a first finger in an adjacent unit where the second finger in the unit is adjacent to the first finger in the adjacent unit. Referring to FIG. 9, a second pitch p₂ may indicate a distance along the first direction X between the second finger 913 in the unit 921 and the first finger 914 in the adjacent unit to the right. For the reasons described above, the second pitch p₂ may vary with the second direction Y and may be indicated by p₂(y). Thus, a pitch between adjacent fingers in the IDT 930 may vary along the second direction Y and vary along the first direction X as p₁(y) may be different from p₂(y).

In an aspect, the unit 921 may be referred to as a pitch conserving IDT pair when the average pitch (e.g., the averaged p₁(y)) for the pair of IDT fingers is a constant such as (p₁₀+p₂₀)/2.

In an aspect, the unit 921 may be referred to as pitch conserving IDT fingers when (p₁(y)+p₂(y))/2 is a constant such as (p₁₀+p₂₀)/2. Accordingly, p₁(y)+p₂(y) is a constant such as p₁₀+p₂₀.

In an aspect, a unit pitch pᵤₙᵢₜ indicating a distance along the first direction X between two adjacent units of the plurality of units of fingers may remain unchanged. The unit pitch pᵤₙᵢₜ may be defined or measured using any other suitable methods, such as those described in the disclosure (e.g., similar or identical to those shown in FIGS. 2A and 6-7). Referring to FIG. 9, the unit pitch pᵤₙᵢₜ may be defined a center-to-center distance between the first fingers in two adjacent units, such as a distance between a center of the first finger 912 in the unit 621 and a center of the first finger 914 in the adjacent unit, such as pᵤₙᵢₜ=p₁(y)+p₂(y) (e.g., p₁₀+p₂₀). The unit pitch pᵤₙᵢₜ may remain unchanged (e.g., a constant) along the first direction X.

In an aspect, the unit 921 may include multiple regions, such as (i) a first segment 941 that is between the first finger 912 and the second finger 913, (ii) a portion (e.g., 50%) of a second segment 942, and (iii) a portion (e.g., 50%) of a second segment 943. The second segment 942 may be a region between the second finger 911 of another unit that is adjacent to the unit 921 on one side (e.g., the left side) and the first finger 912 in the unit 621. The second segment 943 may be a region between the second finger 913 of the unit 921 and the first finger 914 in the adjacent unit. The unit pitch pᵤₙᵢₜ may be defined or measured as pᵤₙᵢₜ=p₂(y)/2+p₁(y)+p₂(y)/2 which is a distance between a center of the second segment 942 and a center of the second segment 943.

In an aspect, the unit pitch pᵤₙᵢₜ between first two adjacent units (e.g., the unit 921 and the adjacent unit to the left of the unit 921) is identical (or substantially identical) to the unit pitch between second two adjacent units (e.g., the units 921 and the adjacent unit to the right of the unit 921).

The unit pitch pᵤₙᵢₜ between the two adjacent units (e.g., the units 921 and the adjacent unit to the right of the unit 921) at a location y of the second direction Y may be equal to a sum of the first pitch p₁(y) between the first finger and the second finger in one (e.g., the unit 921) of the two adjacent units at the location y and a second pitch p₂(y) between the second finger (e.g., 913) in the one (e.g., the unit 621) of the two adjacent units and the first finger (e.g., 914) in another unit (e.g., the adjacent unit to the right of the unit 921) of the two adjacent units at the location y.

As described above, the unit pitch pᵤₙᵢₜ may be conserved along the first direction X (e.g., different units have the identical the unit pitch pᵤₙᵢₜ) and along the second direction Y (e.g., the unit pitch pᵤₙᵢₜ of a single unit such as the unit 921 may be a constant p₁₀+p₂₀ that does not depend on the location Y). The average pitch of the unit 921 may be constant in both the first direction X and the second direction Y. The plurality of units of fingers in the IDT 930 may be referred to as pitch conserving if the unit pitch pᵤₙᵢₜ is conserved along the first direction X and/or along the second direction Y. The plurality of units of fingers in the IDT 930 may be referred to as pitch conserving if the average pitch of the unit 921 may be constant in the first direction X and/or the second direction Y.

FIG. 10 shows an example of units of IDT fingers where a first finger in the unit of the plurality of units of fingers may include a first plurality of linear segments, and an adjacent pair of linear segments in the first plurality of linear segments have different slopes and intercepts at a vertex. FIG. 10 shows a top view of a portion of a bulk acoustic resonator 1000 including an IDT 1030 according to an aspect of the disclosure, although the individual components of the bulk acoustic resonator 1000 are not shown in detail.

The bulk acoustic resonator 1000 may include a piezoelectric layer (not shown) and a first busbar 1032 and a second busbar 1034 that are disposed on a surface of the piezoelectric layer and extend along the first direction X. The first busbar 1032 and the second busbar 1034 may be similar or identical to the first busbar 932 and the second busbar 934 in FIG. 9, respectively.

The IDT 1030 can include a plurality of units of fingers that are adjacent to each other. In an aspect, each unit of the plurality of units of fingers may include a first finger that extends from the first busbar 1032 and a second finger that extends from the second busbar 1034.

FIG. 10 shows an example of a unit 1021 of the plurality of units of fingers. In particular, the unit 1021 of the plurality of units of fingers includes a first finger 1012 and a second finger 1013. A finger 1011 extends from the second busbar 1034 and may be included in a unit that is to the left of the unit 1021. A finger 1014 extends from the first busbar 1032 and may be included in a unit that is to the right of the unit 1021.

In an aspect, the first finger 1012 in the unit 1021 may include a first plurality of linear segments A-C. An adjacent pair of linear segments A-C in the first finger 1012 may have different slopes and may intercept at vertices V3-V4, respectively. A number of the first plurality of linear segments in the first finger 1012 is 3.

The second finger 1013 in the unit 1021 may have any suitable shape, such as a linear shape, a nonlinear shape, or the like. In the example shown in FIG. 10, the second finger 1013 includes a second plurality of linear segments A-C that may have different slopes and intercept at vertices V5-V6. A shape and a size of the second finger 1013 may be identical to or different from to a shape and a size of the first finger 1012, respectively. In the example shown in FIG. 10, the first finger 1012 and the second finger 1013 have the identical shape and the identical size. In an example, a first location (e.g., indicated by the location of the vertex V3) of the first finger 1012 may be shifted from a second location (e.g., indicated by the location of the vertex V5) of the second finger 1013 along the second direction Y.

It should be appreciated that the descriptions with reference to FIG. 9 may be suitably adapted to FIG. 10. A first pitch p₁ indicating a distance along the first direction X between the first finger 1012 and the second finger 1013 in the unit 1021 may vary. The first pitch p₁ may vary with the second direction Y and may be indicated by p₁(y). Referring to FIG. 10, an average pitch for the unit 1021 including the IDT finger pair 1012 and 1013 is p₀. In an example, p₁(y) is p₁₀ when the y location is between a position y₁ that is close to the first busbar 1032 and a position yᵥ₄ which is the y location of V4. In an example, p₁(y) is p₂₀ when the y location is between a position yᵥ₃ which is the y location of V6 and a position yᵥ₂ which is the y location of V3. In an example, p₁(y) is p₃₀ when the y location is between a position y₂ that is close to the second busbar 1034 and a position yᵥ₁ which is the y location of V5. The average pitch for the unit 1021 p₀ may be equal to p₂₀, which is also (p₁₀+p₃₀)/2. The pitch p₁₀ may refer to a center-to-center distance between the segments C of the IDT fingers 1012 and 1013. The pitch p₂₀ may refer to a center-to-center distance between the segments B of the IDT fingers 1012 and 1013. The pitch p₃₀ may refer to a center-to-center distance between the segments A of the IDT fingers 1012 and 1013.

A second pitch p₂ may indicate a distance along the first direction X between a second finger in a unit and a first finger in an adjacent unit where the second finger in the unit is adjacent to the first finger in the adjacent unit. Referring to FIG. 10, a second pitch p₂ may indicate a distance along the first direction X between the second finger 1013 and the first finger 1014 in the adjacent unit to the right. The second pitch p₂ may vary with the second direction Y and may be indicated by p₂(y). Thus, a pitch between adjacent fingers in the IDT 1030 may vary along the second direction Y and vary along the first direction X as p₁(y) may be different from p₂(y).

In an aspect, the unit 1021 may be referred to as a pitch conserving IDT pair similarly as described in FIG. 9. A unit pitch pᵤₙᵢₜ indicating a distance along the first direction X between two adjacent units of the plurality of units of fingers may be described similarly as that in FIG. 9.

In an aspect, the unit pitch pᵤₙᵢₜ may remain unchanged (i.e., constant or substantially constant). The unit pitch pᵤₙᵢₜ may be defined or measured using any other suitable methods, such as those described in the disclosure (e.g., similar or identical to those shown in FIGS. 2A, 6-7, and 9). Referring to FIG. 10, the unit pitch pᵤₙᵢₜ may be defined a center-to-center distance between the first fingers in two adjacent units, such as a distance between a center of the first finger 1012 in the unit 1021 and a center of the first finger 1014 in the adjacent unit, such as pᵤₙᵢₜ=p₁(y)+p₂(y) (e.g., p₁₀+p₃₀ which is also 2p₀). The unit pitch pᵤₙᵢₜ may remain unchanged (e.g., a constant) along the first direction X.

In an aspect, the unit pitch pᵤₙᵢₜ between first two adjacent units (e.g., the unit 1021 and the adjacent unit to the left of the unit 1021) is identical to the unit pitch between second two adjacent units (e.g., the units 1021 and the adjacent unit to the right of the unit 1021).

As described above, the unit pitch pᵤₙᵢₜ may be conserved along the first direction X (e.g., different units have the identical the unit pitch pᵤₙᵢₜ) and along the second direction Y (e.g., the unit pitch pᵤₙᵢₜ of a single unit such as the unit 1021 may be a constant p₁₀+p₃₀ (or 2p₂₀) that does not depend on the location Y). The average pitch of the unit 1021 may be constant in both the first direction X and the second direction Y. The plurality of units of fingers in the IDT 1030 may be referred to as pitch conserving if the unit pitch pᵤₙᵢₜ is conserved along the first direction X and/or along the second direction Y. The plurality of units of fingers in the IDT 1030 may be referred to as pitch conserving if the average pitch of the unit 1021 may be constant in the first direction X and/or the second direction Y.

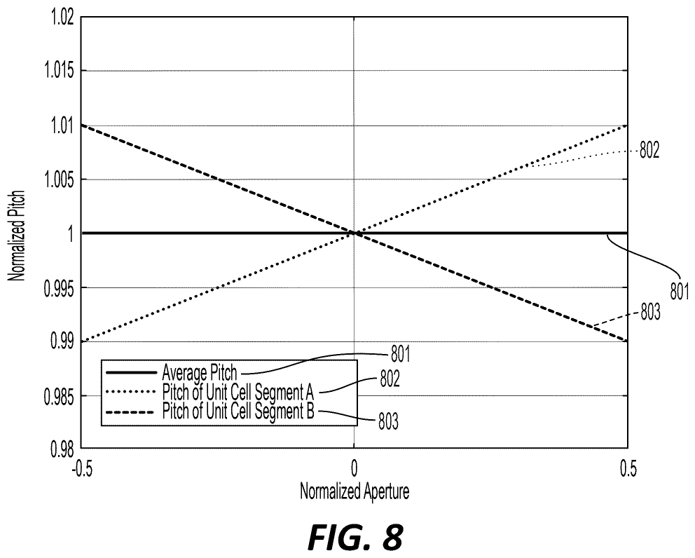

In addition to a linear shape (e.g., shown in FIGS. 6-7) and a nonlinear shape including multiple linear segments, the first finger in the unit of the plurality of units may have an oval-shape (or generally a curved shaped), such as shown in FIG. 11. FIG. 11 shows an example of units of IDT fingers where a first finger 1112 in the unit 1121 of the plurality of units of fingers has an oval shape. A second finger 1113 in the unit 1121 may have any suitable shape, such as a linear shape, a nonlinear shape, or the like. In the example shown in FIG. 11, the second finger 1113 has an oval-shape (or generally a curved shaped). The oval shape of the second finger 1113 and the oval-shape of the first finger may be mirror symmetric with respect to a line 1150 that is at a center of the unit 1121.

In an example, a first pitch p₁ (e.g., p₁(y)) indicating a distance along the first direction X between the first finger 1112 and the second finger 1113 in the unit 1121 may vary. For example, p₁(y) increases from pₘᵢₙ to pₘₐₓ as the y position moves from a position y₁ that is close to the first busbar 1132 to a middle position y_{mid} between the first busbar 1132 and the second busbar 1134, and p₁(y) decreases from pₘₐₓ to pₘᵢₙ as the y position moves from y_{mid} to a position y₂ that is close to the second busbar 1134. Similar to the IDTs structures (e.g., the IDTs 630, 930, and 1030) described above, the unit 1121 in the IDT 1130 may be referred to as pitch conserving unit.

According to an exemplary aspect, an average pitch for the unit 1121 is p₀ which is (pₘₐₓ+pₘᵢₙ)/2.

A second pitch p₂ may indicate a distance along the first direction X between a second finger in a unit and a first finger in an adjacent unit where the second finger in the unit is adjacent to the first finger in the adjacent unit. The second pitch p₂ may indicate a distance along the first direction X between the second finger 1113 in the unit 1121 and the first finger 1114 in the adjacent unit to the right. For the reasons described above, the second pitch p₂ may vary with the second direction Y and may be indicated by p₂(y). Thus, a pitch between adjacent fingers in the IDT 1130 may vary along the second direction Y and vary along the first direction X as p₁(y) may be different from p₂(y).

In an aspect, the unit 1121 may be referred to as a pitch conserving IDT pair when the average pitch (e.g., the averaged p₁(y)) for the pair of IDT fingers is a constant such as (pₘₐₓ+pₘᵢₙ)/2.

As similarly described above, a unit pitch pᵤₙᵢₜ indicating a distance along the first direction X between two adjacent units of the plurality of units of fingers may remain unchanged. The unit pitch pᵤₙᵢₜ may be defined or measured using any other suitable methods, such as those described in the disclosure. Referring to FIG. 11, the unit pitch pᵤₙᵢₜ may be defined a center-to-center distance between the first fingers in two adjacent units, such as a distance between a center of the first finger 1112 in the unit 1121 and a center of the first finger 1114 in the adjacent unit, such as pᵤₙᵢₜ=p₁(y)+p₂(y) (e.g., pₘₐₓ+pₘᵢₙ). The unit pitch pᵤₙᵢₜ may remain unchanged (e.g., a constant) along the first direction X.

In an aspect, the unit pitch pᵤₙᵢₜ between first two adjacent units (e.g., the unit 1121 and the adjacent unit to the left of the unit 1121) is identical to the unit pitch between second two adjacent units (e.g., the units 1121 and the adjacent unit to the right of the unit 1121).

The unit pitch pᵤₙᵢₜ between the two adjacent units (e.g., the units 1121 and the adjacent unit to the right of the unit 1121) at a location y of the second direction Y may be equal to a sum of the first pitch p₁(y) between the first finger and the second finger in one (e.g., the unit 1121) of the two adjacent units at the location y and a second pitch p₂(y) between the second finger (e.g., 1113) in the one (e.g., the unit 1121) of the two adjacent units and the first finger (e.g., 1114) in another unit (e.g., the adjacent unit to the right of the unit 1121) of the two adjacent units at the location y.

As described above, the unit pitch pᵤₙᵢₜ may be conserved along the first direction X (e.g., different units have the identical the unit pitch pᵤₙᵢₜ) and along the second direction Y (e.g., the unit pitch pᵤₙᵢₜ of a single unit such as the unit 1121 may be a constant pₘₐₓ+pₘᵢₙ that does not depend on the location Y). The average pitch of the unit 1121 may be constant in both the first direction X and the second direction Y. The plurality of units of fingers in the IDT 1130 may be referred to as pitch conserving if the unit pitch pᵤₙᵢₜ is conserved along the first direction X and/or along the second direction Y. The plurality of units of fingers in the IDT 1130 may be referred to as pitch conserving if the average pitch of the unit 1121 may be constant in the first direction X and/or the second direction Y.

Referring to FIG. 11, the pitch (e.g., pₘₐₓ) between the first finger 1112 and the second finger 1113 at a mid-location y_{mid} between the first busbar 1132 and the second busbar 1134 along the second direction Y may be larger than the pitch (e.g., pₘᵢₙ) between the first finger 1112 and the second finger 1113 at an edge location (e.g., y₁ or y₂) along the second direction Y.

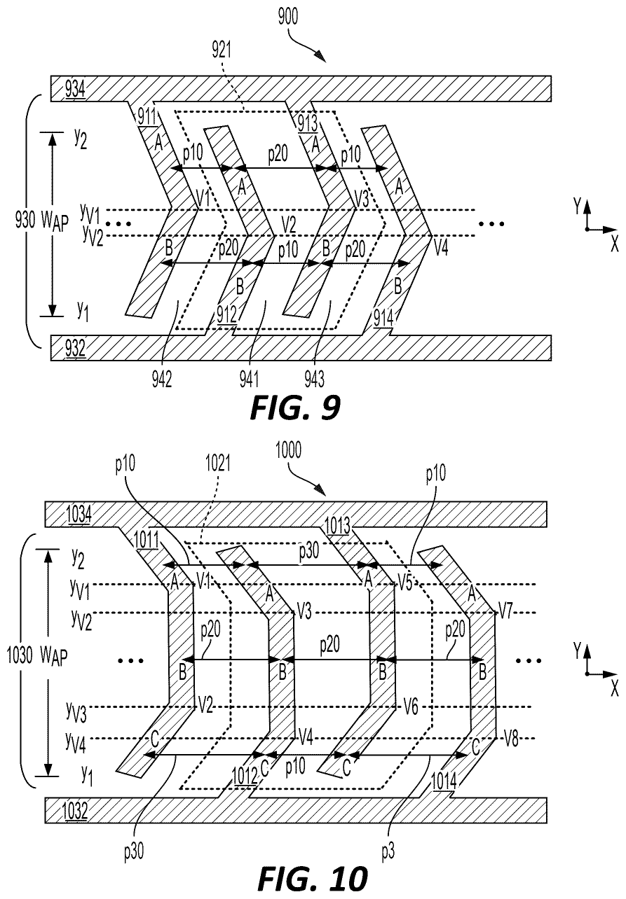

FIG. 12 shows a bulk acoustic resonator 1200 including an IDT 1230. The IDT 1230 includes a plurality of units of IDT fingers where a first finger 1212 in the unit 1221 of the plurality of units of fingers has a sinusoidal shape. A second finger 1213 in the unit 1221 may have any suitable shape, such as a linear shape, a nonlinear shape, or the like. In the example shown in FIG. 12, the second finger 1213 has a sinusoidal shape. The shape of the second finger 1213 and the shape of the first finger may be mirror symmetric with respect to a line 1250 that is at a center of the unit 1221. Finger 1211 illustrates a second finger in an adjacent unit to the left and finger 1214 illustrates a first finger in an adjacent unit to the right.

In an example, a first pitch p₁ (e.g., p₁(y)) indicating a distance along the first direction X between the first finger 1212 and the second finger 1213 in the unit 1221 may vary. For example, p₁(y) increases from pₘᵢₙ to pₘₐₓ as the y position moves from a position y₁ that is close to the first busbar 1232 to a position y₂ that is close to the second busbar 1234. Similar to the IDTs structures (e.g., the IDTs 630, 930, 1030, and 1130) described above, the unit 1221 in the IDT 1230 may be referred to as pitch conserving unit. An average pitch for the unit 1221 is p₀ which is (pₘₐₓ+pₘᵢₙ)/2.

A second pitch p₂ may indicate a distance along the first direction X between a second finger in a unit and a first finger in an adjacent unit where the second finger in the unit is adjacent to the first finger in the adjacent unit. The second pitch p₂ may indicate a distance along the first direction X between the second finger 1213 in the unit 1221 and the first finger 1214 in the adjacent unit to the right. For the reasons described above, the second pitch p₂ may vary with the second direction Y and may be indicated by p₂(y). Thus, a pitch between adjacent fingers in the IDT 1230 may vary along the second direction Y and vary along the first direction X as p₁(y) may be different from p₂(y).

In an aspect, the unit 1221 may be referred to as a pitch conserving IDT pair when the average pitch (e.g., the averaged p₁(y)) for the pair of IDT fingers is a constant such as (pₘₐₓ+pₘᵢₙ)/2.

As similarly described above, a unit pitch pᵤₙᵢₜ indicating a distance along the first direction X between two adjacent units of the plurality of units of fingers may remain unchanged (i.e., constant or substantially constant). The unit pitch pᵤₙᵢₜ may be defined or measured using any other suitable methods, such as those described in the disclosure. Referring to FIG. 12, the unit pitch pᵤₙᵢₜ may be defined a center-to-center distance between the first fingers in two adjacent units, such as a distance between a center of the first finger 1212 in the unit 1221 and a center of the first finger 1214 in the adjacent unit, such as pᵤₙᵢₜ=p₁(y)+p₂(y) (e.g., pₘₐₓ+pₘᵢₙ). The unit pitch pᵤₙᵢₜ may remain unchanged (e.g., a constant) along the first direction X.

In an aspect, the unit pitch pᵤₙᵢₜ between first two adjacent units (e.g., the unit 1221 and the adjacent unit to the left of the unit 1221) is identical or substantially identical to the unit pitch between second two adjacent units (e.g., the units 1221 and the adjacent unit to the right of the unit 1221).

The unit pitch pᵤₙᵢₜ between the two adjacent units (e.g., the units 1221 and the adjacent unit to the right of the unit 1221) at a location y of the second direction Y may be equal to a sum of the first pitch p₁(y) between the first finger and the second finger in one (e.g., the unit 1221) of the two adjacent units at the location y and a second pitch p₂(y) between the second finger (e.g., 1213) in the one (e.g., the unit 1221) of the two adjacent units and the first finger (e.g., 1214) in another unit (e.g., the adjacent unit to the right of the unit 1221) of the two adjacent units at the location y.

As described above, the unit pitch pᵤₙᵢₜ may be conserved along the first direction X (e.g., different units have the identical the unit pitch pᵤₙᵢₜ) and along the second direction Y (e.g., the unit pitch pᵤₙᵢₜ of a single unit such as the unit 1221 may be a constant pₘₐₓ+pₘᵢₙ that does not depend on the location Y). The average pitch of the unit 1221 may be constant in both the first direction X and the second direction Y. The plurality of units of fingers in the IDT 1230 may be referred to as pitch conserving if the unit pitch pᵤₙᵢₜ is conserved along the first direction X and/or along the second direction Y. The plurality of units of fingers in the IDT 1230 may be referred to as pitch conserving if the average pitch of the unit 1221 may be constant in the first direction X and/or the second direction Y.

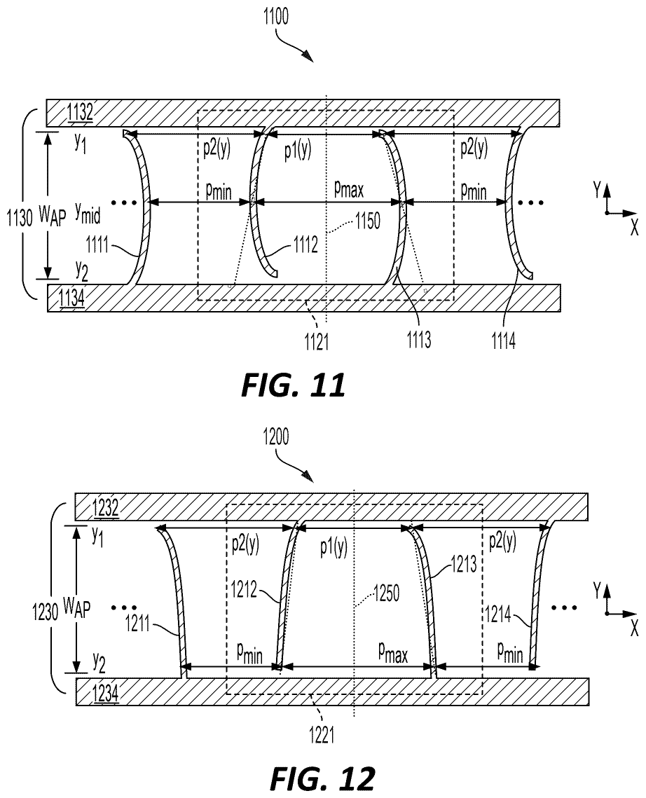

FIG. 13 shows a bulk acoustic resonator 1300 including an IDT 1330. The IDT 1330 includes a plurality of units of IDT fingers where a first finger 1312 in the unit 1321 of the plurality of units of fingers has a triangular shape. A second finger 1313 in the unit 1321 may have any suitable shape, such as a linear shape, a nonlinear shape, or the like. In the example shown in FIG. 13, the second finger 1313 has a triangular shape. The shape of the second finger 1313 and the shape of the first finger may be mirror symmetric with respect to a line 1350 that is at a center of the unit 1321. Finger 1311 illustrates a second finger in an adjacent unit to the left and finger 1314 illustrates a first finger in an adjacent unit to the right.

In an example, a first pitch p₁ (e.g., p₁(y)) indicating a distance along the first direction X between the first finger 1312 and the second finger 1313 in the unit 1321 may vary. For example, p₁(y) increases from pₘᵢₙ to pₘₐₓ as the y position moves from a position y₁ that is close to the first busbar 1332 to a middle position y_{mid} between the first busbar 1332 and the second busbar 1334, and p₁(y) decreases from pₘₐₓ to pₘᵢₙ as the y position moves from y_{mid} to a position y₂ that is close to the second busbar 1334. Similar to the IDTs structures (e.g., the IDTs 630, 930, 1030, 1130, and 1230) described above, the unit 1321 in the IDT 1330 may be referred to as pitch conserving unit. An average pitch for the unit 1321 is p₀ which is (pₘₐₓ+pₘᵢₙ)/2.

Similar to the IDTs structures (e.g., the IDTs 630, 930, 1030, 1130, and 1230) described above, the unit 1321 in the IDT 1330 may be referred to as pitch conserving unit. An average pitch for the unit 1321 is p₀ which is (pₘₐₓ+pₘᵢₙ)/2 according to the exemplary aspect.

A second pitch p₂ may indicate a distance along the first direction X between a second finger in a unit and a first finger in an adjacent unit where the second finger in the unit is adjacent to the first finger in the adjacent unit. The second pitch p₂ may indicate a distance along the first direction X between the second finger 1313 in the unit 1321 and the first finger 1314 in the adjacent unit to the right. For the reasons described above, the second pitch p₂ may vary with the second direction Y and may be indicated by p₂(y). Thus, a pitch between adjacent fingers in the IDT 1330 may vary along the second direction Y and vary along the first direction X as p₁(y) may be different from p₂(y).

In an aspect, the unit 1321 may be referred to as a pitch conserving IDT pair when the average pitch (e.g., the averaged p₁(y)) for the pair of IDT fingers is a constant such as (pₘₐₓ+pₘᵢₙ)/2.

As similarly described above, a unit pitch pᵤₙᵢₜ indicating a distance along the first direction X between two adjacent units of the plurality of units of fingers may remain unchanged. The unit pitch pᵤₙᵢₜ may be defined or measured using any other suitable methods, such as those described in the disclosure. Referring to FIG. 13, the unit pitch pᵤₙᵢₜ may be defined a center-to-center distance between the first fingers in two adjacent units, such as a distance between a center of the first finger 1312 in the unit 1321 and a center of the first finger 1314 in the adjacent unit, such as pᵤₙᵢₜ=p₁(y)+p₂(y) (e.g., pₘₐₓ+pₘᵢₙ). The unit pitch pᵤₙᵢₜ may remain unchanged (e.g., a constant) along the first direction X.

In an aspect, the unit pitch pᵤₙᵢₜ between first two adjacent units (e.g., the unit 1321 and the adjacent unit to the left of the unit 1321) is identical to the unit pitch between second two adjacent units (e.g., the units 1321 and the adjacent unit to the right of the unit 1321).

The unit pitch pᵤₙᵢₜ between the two adjacent units (e.g., the units 1321 and the adjacent unit to the right of the unit 1321) at a location y of the second direction Y may be equal to a sum of the first pitch p₁(y) between the first finger and the second finger in one (e.g., the unit 1321) of the two adjacent units at the location y and a second pitch p₂(y) between the second finger (e.g., 1313) in the one (e.g., the unit 1321) of the two adjacent units and the first finger (e.g., 1314) in another unit (e.g., the adjacent unit to the right of the unit 1321) of the two adjacent units at the location y.

As described above, the unit pitch pᵤₙᵢₜ may be conserved along the first direction X (e.g., different units have the identical the unit pitch pᵤₙᵢₜ) and along the second direction Y (e.g., the unit pitch pᵤₙᵢₜ of a single unit such as the unit 1321 may be a constant pₘₐₓ+pₘᵢₙ that does not depend on the location Y). The average pitch of the unit 1321 may be constant in both the first direction X and the second direction Y. The plurality of units of fingers in the IDT 1330 may be referred to as pitch conserving if the unit pitch pᵤₙᵢₜ is conserved along the first direction X and/or along the second direction Y. The plurality of units of fingers in the IDT 1330 may be referred to as pitch conserving if the average pitch of the unit 1321 may be constant in the first direction X and/or the second direction Y.

In some examples, such as described in FIGS. 6 and 11-13, the IDT geometries may have symmetry, such as the mirror symmetry (e.g., in the second direction Y) as described above, with respect to the center line in the respective unit and may have the same peak-peak variation in pitch within the unit cell.

The IDT geometries such as shown in FIGS. 9-13 may have advantages, such as ease of drawing, for example, using CAD, a relative location of an unchirped portion of the IDT, a different distribution function of a pitch variation (e.g., a non-square distribution), and the like. Comparing the linear IDT structure in FIG. 6 and a nonlinear IDT structure shown in FIGS. 9-13, a distribution function (e.g., a histogram) of a pitch variation may be flat (e.g., a square distribution) for the IDT 630 in FIG. 6, and a distribution function (e.g., a histogram) of a pitch variation is not flat (e.g., a non-square distribution) for the IDT 930 in FIG. 9 or 1130 in FIG. 11.

In an aspect, the first pitch p₁(y) and the second pitch p₂(y) of some IDTs (e.g., the IDT 630, 1130, 1230, and 1330) may vary continuously along the second direction Y. In an example, such as shown in FIGS. 9-10, the first pitch p₁(y) and the second pitch p₂(y) may remain constant in certain ranges of y locations (e.g., from yᵥ₁ to y₂ or from y₁ to yᵥ₂ in FIG. 9).

In the description of the various IDT structures such as in FIGS. 6-7 and 9-13, the unit of the respective IDT structure includes the first finger and the second finger. In an aspect, such as described in FIGS. 6-7 and 9-13, an adjacent unit (e.g., the unit 622) is positioned next to the unit (e.g., the unit 621) such that the adjacent unit is at the same y location along the second direction Y as that of the unit, and the adjacent unit is shifted by the unit pitch along the first direction X. In an example, the unit (e.g., the unit 621) may repeat (e.g., having the same y location and being shifted by the unit pitch along the first direction X) a number of times in the IDT and then a unit (e.g., the unit 921) with fingers having different shapes may be added to the IDT and may repeat a number of times, and the like to form the IDT.

According to the exemplary aspects, using the skewed and conserved pitches in the IDT itself may be advantageous than using similar shapes in a component different from the IDT. For example, using the skewed and conserved pitches in the IDT itself may reduce a number of parts required and a number of steps associated with manufacturing the extra element, and may reduce the footprint of the resonator.

In an example, the IDT described in the disclosure using the first finger and the second finger whose shapes result in the skewed and conserved pitches in the same IDT of a resonator. Thus, the skewed and conserved pitches within the IDT may reduce spurious modes of the IDT response itself, rather than by other components outside of the IDT. As spurs may have a higher sensitivity to a pitch change than the main mode, the IDT structures (e.g., which unit is selected) may be selected to disrupt certain spurious modes.

The IDT fingers in the disclosure are configured to excite resonance (e.g., the main XBAR mode) in addition to suppress spurious modes.

Different units of pairs of IDT fingers may be combined into the same IDT. For example, an IDT can include one or more of a number of units 621, a number of units 921, a number of units 1021, a number of units 1121, a number of units 1221, a number of units 1321, and/or the like. The units 621, 921, 1021, 1121, 1221, and/or 1321 may be positioned in any suitable combinations and arrangements. In addition to one or more of the units 621, 921, 1021, 1121, 1221, and/or 1321, the IDT may include a plurality of IDT fingers such as shown in FIG. 1A.

As described in FIG. 6, the angle θ in FIGS. 6-7 or the deviation of the IDTs described in FIGS. 6-7 and 9-13 from the IDT 130 may be relatively small, and thus the IDT structures and/or the shapes of the first fingers and the second fingers may serve as a water mark of the resonator.

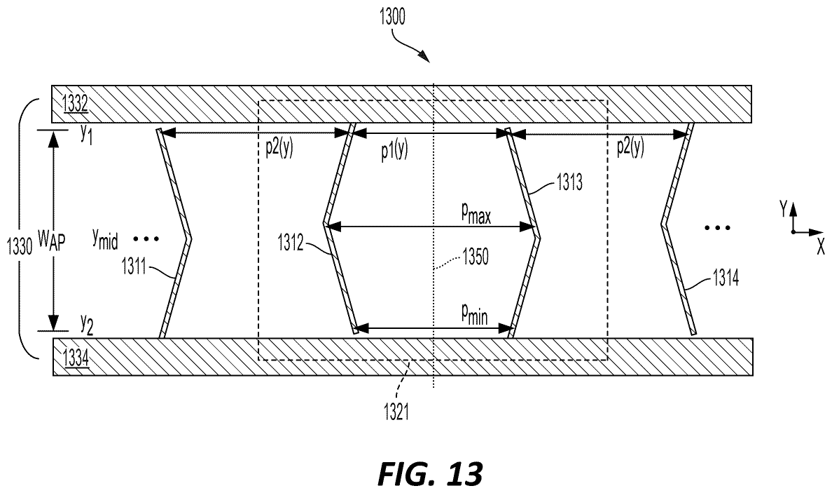

FIGS. 14-18 compare the performance of three bulk acoustic resonators with the three respective IDT configurations according to an aspect of the disclosure, which can include (i) a control configuration where the IDT fingers extend along the second direction Y (e.g., each of the IDT finger is parallel to the second direction Y) and thus are similar to the IDT 130 in FIG. 1A; (ii) an IDT configuration having a 2.1% skew where the IDT fingers are described by the IDT 630 in FIGS. 6-7; and (iii) an IDT configuration having a V-shape where the IDT fingers are described by the IDT 930 in FIG. 9. The plots in FIGS. 14-18 are obtained using a finite element method (FEM) simulation.

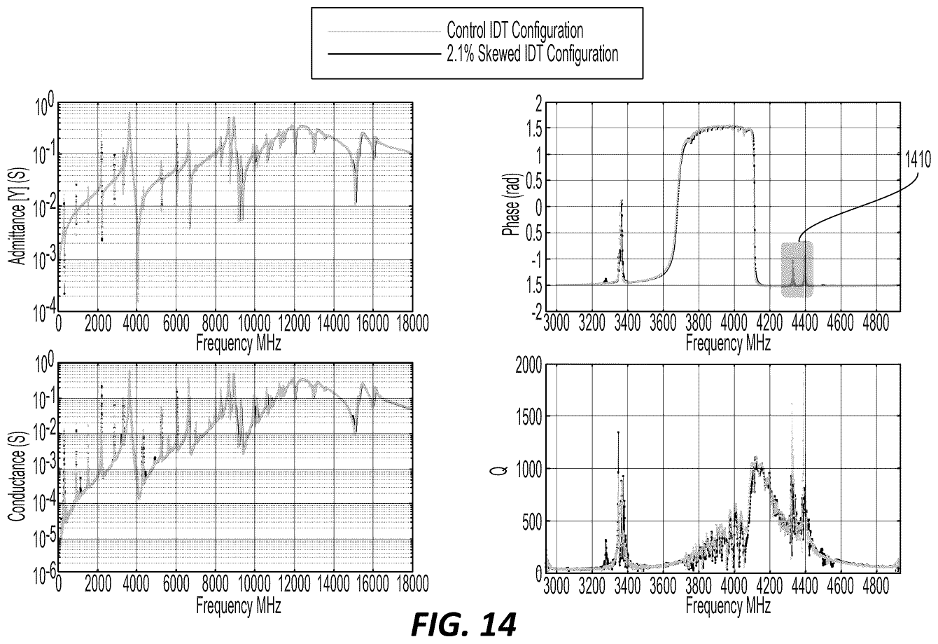

In particular, FIG. 14 shows admittance curves (interchangeably referred to as a Y-parameter) (top-left), conductance curves (bottom-left), phase curves (top-right), and the Q-factor curves (bottom-right) of the control and 2.1% skewed IDT configurations versus a frequency in unit of Mega-Herz (MHz) according to some examples of the disclosure. FIG. 15 shows a zoomed in view of the conductance curves of the control and 2.1% skewed IDT configurations versus a frequency in MHz according to some examples of the disclosure. Referring to the phase curves, a reduction of spur intensity may be obtained by the IDT configuration with the 2.1% skew, as shown by the phase curves 1410 corresponding to the control and 2.1% skewed IDT configurations.

An arrow 1510 in FIG. 15 indicates that there is no apparent effect on the quality factor of the main mode. An arrow 1511 in FIG. 15 indicates that some weak satellite spurs appear, for example, due to the introduction of the 2.1% pitch variation using the IDT 630.

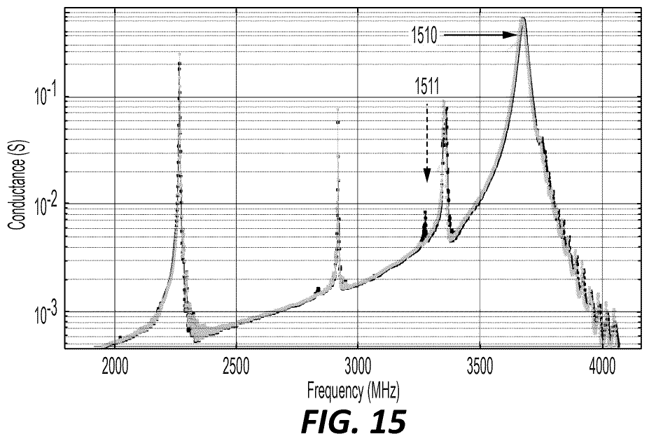

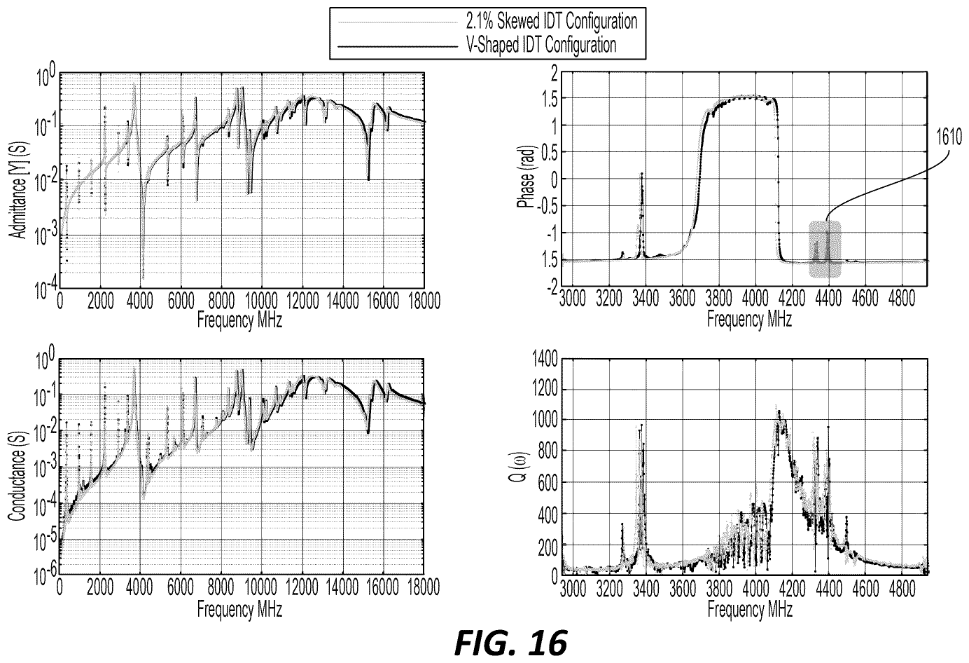

FIG. 16 shows admittance curves (top-left), conductance curves (bottom-left), phase curves (top-right), and the Q-factor curves (bottom-right) of the 2.1% skewed and V-shaped IDT configurations versus a frequency in unit of MHz according to some examples of the disclosure. FIG. 17 shows a zoomed in view of the conductance curves of the 2.1% skewed and V-shaped IDT configurations versus a frequency in MHz according to some examples of the disclosure. Both 2.1% skewed and V-shaped IDT configurations show similar benefits (e.g., including spur reduction as shown by the phase curves 1610 corresponding to the 2.1% skewed and V-shaped IDT configurations) and side effects (e.g., new spurs indicated by an arrow 1711 in FIG. 17). Again, it is shown that an arrow 1710 in FIG. 17 indicates that there is no apparent effect on the quality factor of the main mode.

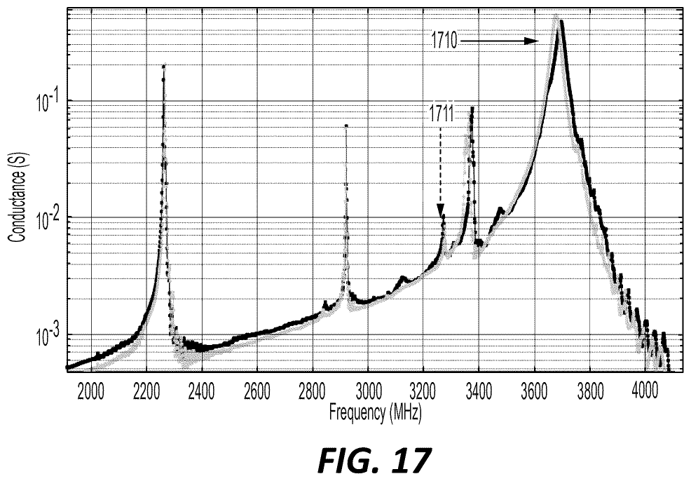

FIG. 18 shows examples of parameters used in the IDT configuration (e.g., SkewB) and similar IDT configurations (SkewC, SkewD, SkewE, SkewG, and SkewH) with different pitch variations). The parameters include the average pitch p0, the mark of the fingers, the width of the aperture, the busbar to electrode gap, the IDT angle (e.g., the tilt angle θ in FIG. 6), the pitch variation (δp) across aperture, and the percentage pitch variation (δp/p) across aperture. For the 2.1% skewed IDT configuration (e.g., SkewB), the average pitch p0 is 2 microns, the mark of the fingers is 0.4 microns, the width of the aperture is 60 microns, the busbar to electrode gap is 5 microns, the IDT angle (e.g., the tilt angle θ in FIG. 6) is 0.04°, the pitch variation (δp) across aperture is 0.04 microns, and the percentage pitch variation (δp/p) across aperture is 2.1%.

In an example, a percentage pitch variation that is larger than 4% skew may induce more significant side effects for the 2.1% skewed IDT configuration.

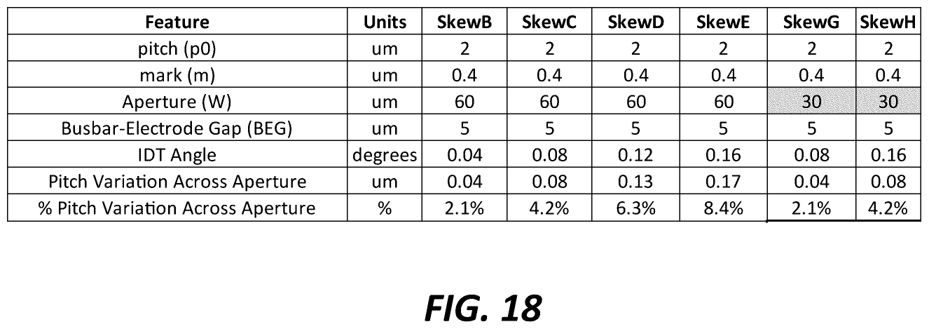

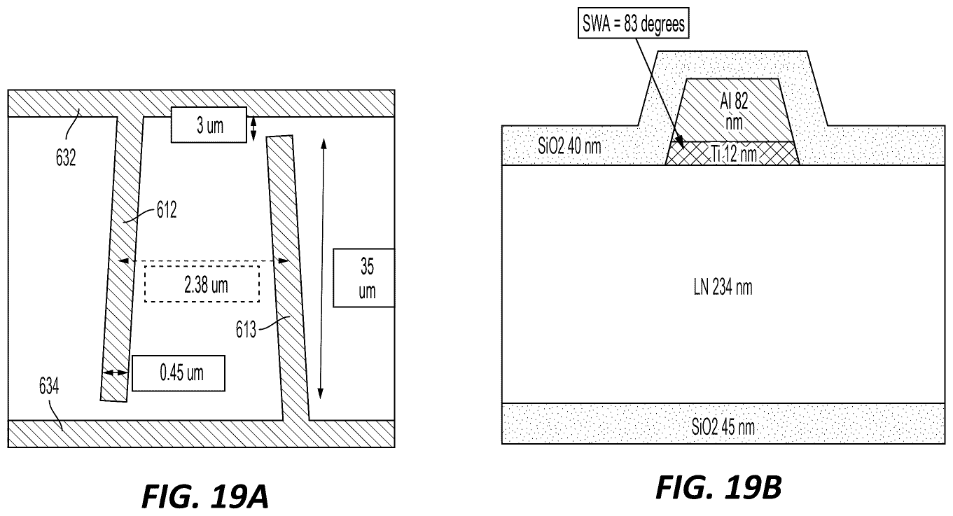

FIGS. 19A, 19B and 20 show an example of the IDT 630 or the 2.1% skewed IDT configuration including a top view (FIG. 19A), a cross-sectional view (FIG. 19B) and a top view in FIG. 20 according to an aspect of the disclosure. Referring to the top view of FIG. 19A, the parameters include the average pitch p0 being 2.38 microns, the mark of the fingers is 0.45 microns, the width of the aperture is 35 microns, the busbar to electrode gap is 3 microns. Referring to the cross-sectional view of FIG. 19B, the exemplary parameters include a thickness of the piezoelectric layer (e.g., lithium niobate) of 234 nm, a thickness tm of the IDT fingers being 94 nm (e.g., a sum of the Al thickness 82 nm and a Ti thickness of 12 nm), a thickness tfd of the dielectric layer over the IDT fingers of 40 nm, and a thickness tbd of the dielectric layer over the IDT fingers of 45 nm. A side wall angle (SWA) is 83°.

A tilt angle θ is shown in FIG. 20. The tilt angle θ of 0° may correspond to the IDT 130, and the tilt angle θ of 0.1 and 0.2° may correspond to the IDT 630.

A table in FIG. 20 shows examples of parameters used in the IDT 130 (e.g., the variant 1 with the tilt angle θ of) 0° and in the 2.1% skewed IDT configuration or the IDT 630 with different variations (e.g., the variants 2-3 with the tilt angle θ of 0.1 and 0.2°). The parameters include the average pitch p0, the mark of the fingers, the SWA, the width of the aperture, a thickness of the Ti layer, a thickness of the Al layer, a thickness of the top oxide (e.g., SiO2), the thickness of the piezoelectric layer (LN), a thickness of the bottom oxide (e.g., SiO2), the busbar to electrode gap, the IDT angle (e.g., the tilt angle θ in FIG. 6 or IDT in FIG. 20), the pitch variation (δp) across aperture, and the percentage pitch variation (δp/p) across aperture.

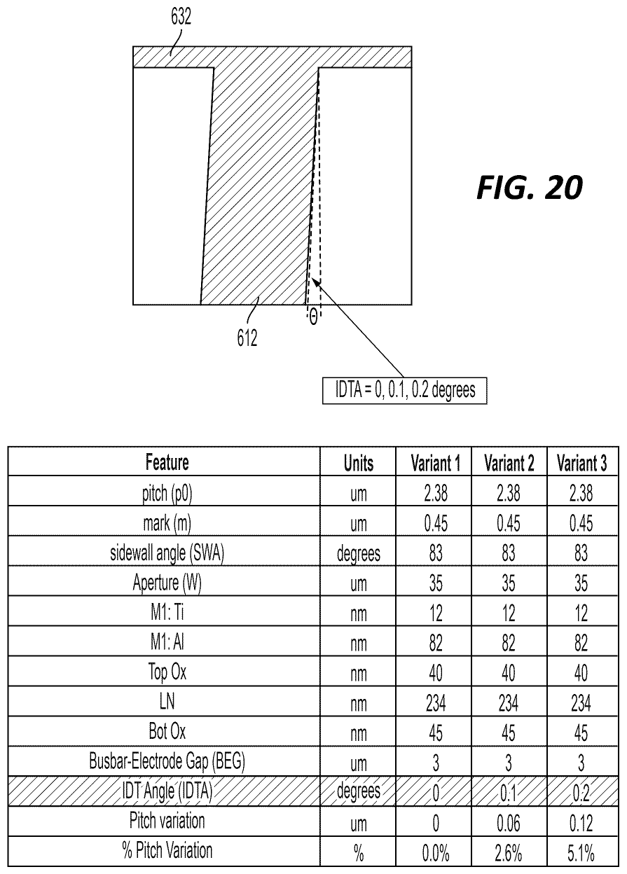

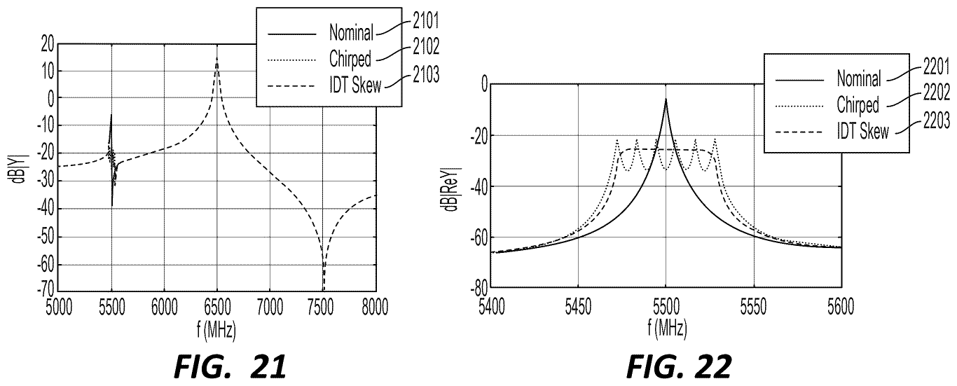

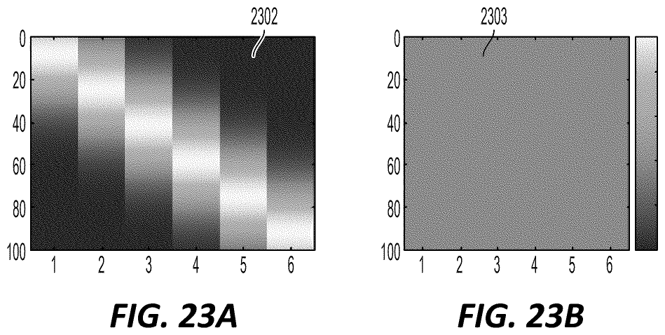

FIGS. 21-23 compare magnitudes 2101-2103 of the admittance (FIG. 21), real components 2201-2203 of the admittance (FIG. 22), and spatial heat distributions 2302-2303 by frequency (FIG. 23) of three different IDT configurations according to some examples of the disclosure. The three different IDT configurations may include a configuration that is similar to identical to the IDT 130, a chirped IDT, and a configuration that is similar to identical to the IDT 630.

FIGS. 21-22 illustrate that the IDT 630 using the IDT skew of pitches may suppress spurious modes, and may generate fewer residual ripples (e.g., new spurious modes) than those caused by the chirp configuration. For example, FIG. 22 shows 6 ripples near the frequency of 5.5 GHz associated with the chirp configuration, the 6 ripples are smoothed and reduced by the IDT 630. FIGS. 21-22 indicate that both the chirp configuration and the IDT 630 can suppress the spurious modes.

FIGS. 23A and 23B show that the IDT 630 using the IDT skew of pitches may have less local heating effects than that caused by the chirp configuration. That is, FIGS. 23A and 23B illustrate spatial heat distribution (according to the Y axis) by frequency (in MHz according to the X axis). As illustrated the IDT skewed configuration avoids (or reduces) residual ripple and local heating effects caused by chirping as described above.

In general, the bulk acoustic resonators 600, 900, 1000, 1100, 1200, or 1300 can have the configuration shown above with respect to bulk acoustic resonator 100 of FIG. 1A or 100′ in FIG. 1B. Moreover, the bulk acoustic resonator 600, 900, 1000, 1100, 1200, or 1300 may be implemented according to the various aspects in FIGS. 1A to 3B. It should be appreciated that the busbars may also have a length (e.g., the first direction X) that extends farther than the respective interleaved fingers.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. A bulk acoustic resonator comprising:
a piezoelectric layer;
a first busbar and a second busbar that are disposed on a surface of the piezoelectric layer and that extend along a first direction of the surface of the piezoelectric layer; and
a plurality of units of fingers at a surface of the piezoelectric layer and that are adjacent to each other,
wherein each unit of the plurality of units of fingers includes a first finger that extends from the first busbar and a second finger that extends from the second busbar and that is adjacent to the first finger,
wherein a first pitch of each unit of the plurality of units of fingers indicates a distance along the first direction between the first finger and the second finger in the respective unit, with the first pitch varying along a second direction that is orthogonal to the first direction, and
wherein a unit pitch indicates a center-to-center distance along the first direction between respective first fingers of adjacent units of the plurality of units of fingers that extend from the first busbar, with the unit pitch being substantially constant across the plurality of units of fingers.

2. The bulk acoustic resonator of claim 1, wherein the unit pitch is substantially constant along the second direction.

3. The bulk acoustic resonator of claim 1, wherein the unit pitch between a first two adjacent units is identical to the unit pitch between a second two adjacent units.

4. The bulk acoustic resonator of claim 3, wherein the unit pitch between the first two adjacent units at a location y of the second direction is equal to a sum of the first pitch between the first finger and the second finger in one of the first two adjacent units at the location y and a second pitch between the second finger in the one of the two adjacent units and the first finger in another unit of the first two adjacent units at the location y.

5. The bulk acoustic resonator of claim 4, wherein the first pitch is not equal to the second pitch.

6. The bulk acoustic resonator of claim 1, wherein:
the first finger in a unit of the plurality of units includes a first plurality of linear segments, and
an adjacent pair of linear segments in the first plurality of linear segments has different slopes from each other and intercepts at a vertex.

7. The bulk acoustic resonator of claim 6, wherein:
a shape and a size of the second finger in the unit of the plurality of units are identical to a shape and a size of the first finger in the unit of the plurality of units, respectively; and
respective vertices of the first and second fingers in the unit of the plurality of units are offset relative to each other in the second direction.

8. The bulk acoustic resonator of claim 7, wherein a number of the first plurality of linear segments in the first finger is at least 2, and at least a portion of the first finger and the second finger are V-shaped.

9. The bulk acoustic resonator of claim 6, wherein:
a number of the first plurality of linear segments in the first finger is 2 and the first finger has a V-shape,
the second finger in the unit of the plurality of units has a V-shape that is mirror symmetric with respect to the V-shape of the first finger, and
the first pitch between the first finger and the second finger at a mid-location between the first busbar and the second busbar along the second direction is larger than the first pitch between the first finger and the second finger at an edge location along the second direction.

10. The bulk acoustic resonator of claim 1, wherein:
the first finger in a unit of the plurality of units has a curved shape,
the second finger in the unit of the plurality of units has a curved shape that is mirror symmetric with respect to the curved shape of the first finger, and
the first pitch between the first finger and the second finger at a mid-location between the first busbar and the second busbar along the second direction is larger than the first pitch between the first finger and the second finger at an edge location along the second direction.

11. The bulk acoustic resonator of claim 1, wherein:
the first finger in a unit of the plurality of units has a sinusoidal shape, and
the second finger in the unit of the plurality of units has a sinusoidal shape that is mirror symmetric with respect to the sinusoidal shape of the first finger.

12. A filter device comprising:
a plurality of bulk acoustic resonators connected in parallel, with at least one of the plurality of bulk acoustic resonators including:
a piezoelectric layer;
a first busbar and a second busbar that are disposed on a surface of the piezoelectric layer and that extend along a first direction of the surface of the piezoelectric layer; and
a plurality of units of fingers at a surface of the piezoelectric layer and that are adjacent to each other,
wherein each unit of the plurality of units of fingers includes a first finger that extends from the first busbar and a second finger that extends from the second busbar and that is adjacent to the first finger,
wherein a first pitch of each unit of the plurality of units of fingers indicates a distance along the first direction between the first finger and the second finger in the respective unit, with the first pitch varying along a second direction that is orthogonal to the first direction, and
wherein a unit pitch indicates a center-to-center distance along the first direction between respective first fingers of adjacent units of the plurality of units of fingers that extend from the first busbar, with the unit pitch being substantially constant across the plurality of units of fingers.

13. The filter device of claim 12, wherein, for the at least one of the plurality of bulk acoustic resonators, the unit pitch between two adjacent units of the plurality of units of fingers at a location y of the second direction is equal to a sum of the first pitch between the first finger and the second finger in one of the two adjacent units at the location y and a second pitch between the second finger in the one of the two adjacent units and the first finger in another unit of the two adjacent units at the location y.

14. The filter device of claim 13, wherein the first pitch is not equal to the second pitch.

15. The filter device of claim 12, wherein, for the at least one of the plurality of bulk acoustic resonators:
the first finger in a unit of the plurality of units includes a first plurality of linear segments, and
an adjacent pair of linear segments in the first plurality of linear segments has different slopes from each other and intercepts at a vertex.

16. The filter device of claim 15, wherein:
a shape and a size of the second finger in the unit of the plurality of units are identical to a shape and a size of the first finger in the unit of the plurality of units, respectively; and
respective vertices of the first and second fingers in the unit of the plurality of units are offset relative to each other in the second direction.

17. The filter device of claim 15, wherein:
a number of the first plurality of linear segments in the first finger is 2 and the first finger has a V-shape,
the second finger in the unit of the plurality of units has a V-shape that is mirror symmetric with respect to the V-shape of the first finger, and
the first pitch between the first finger and the second finger at a mid-location between the first busbar and the second busbar along the second direction is larger than the first pitch between the first finger and the second finger at an edge location along the second direction.

18. The filter device of claim 12, wherein, for the at least one of the plurality of bulk acoustic resonators:
the first finger in a unit of the plurality of units has a curved shape,
the second finger in the unit of the plurality of units has a curved shape that is mirror symmetric with respect to the curved shape of the first finger, and
the first pitch between the first finger and the second finger at a mid-location between the first busbar and the second busbar along the second direction is larger than the first pitch between the first finger and the second finger at an edge location along the second direction.

19. The filter device of claim 12, wherein, for the at least one of the plurality of bulk acoustic resonators:
the first finger in a unit of the plurality of units has a sinusoidal shape, and
the second finger in the unit of the plurality of units has a sinusoidal shape that is mirror symmetric with respect to the sinusoidal shape of the first finger.

20. A radio frequency module comprising:
a filter device including plurality of bulk acoustic resonators connected in parallel; and
a radio frequency circuit coupled to the filter device, the filter device and the radio frequency circuit being enclosed within a common package,
wherein at least one of the plurality of bulk acoustic resonators of the filter device includes:
a piezoelectric layer;
a first busbar and a second busbar that are disposed on a surface of the piezoelectric layer and that extend along a first direction of the surface of the piezoelectric layer; and
a plurality of units of fingers at a surface of the piezoelectric layer and that are adjacent to each other,
wherein each unit of the plurality of units of fingers includes a first finger that extends from the first busbar and a second finger that extends from the second busbar and that is adjacent to the first finger,
wherein a first pitch of each unit of the plurality of units of fingers indicates a distance along the first direction between the first finger and the second finger in the respective unit, with the first pitch varying along a second direction that is orthogonal to the first direction, and
wherein a unit pitch indicates a center-to-center distance along the first direction between respective first fingers of adjacent units of the plurality of units of fingers that extend from the first busbar, with the unit pitch being substantially constant across the plurality of units of fingers.
